(19) United States
(12) Patent Application Publication
(10) Pub. No.: US 2026/0221971 A1
(43) Pub. Date: Jul. 30, 2026

(54) DRIVER

(71) Applicant: FARADAY TECHNOLOGY CORPORATION, Hsinchu City (TW)

(72) Inventors: Yu-Cheng HUNG, Hsinchu City (TW); Chin-Chuan Kao, Hsinchu City (TW); Feng-Hsiang Chiu, Hsinchu City (TW)

(21) Appl. No.: 19/348,829

(22) Filed: Oct. 3, 2025

(30) Foreign Application Priority Data
Jan. 24, 2025 (TW) 114103630

(51) Int. Cl. H03K 17/687

(52) U.S. Cl. CPC H03K 17/6872

(57) ABSTRACT

A driver is provided. The driver includes a switching-signal generation circuit, a comparison circuit, a driving circuit, and a port control module. The switching-signal generation circuit generates a positive pull-up switching-signal, a negative pull-up switching-signal, a positive pull-down switching-signal, and a negative pull-down switching-signal. A non-inverting input-terminal of the comparison circuit is electrically connected to a driver output node. An inverting output-terminal of the comparison circuit is electrically connected to a pull-up transistor-gating node. The driving circuit includes a pull-up circuit and a pull-down circuit. The pull-up circuit and the pull-down circuit selectively adjust the voltage of the driver output node according to the voltages of the pull-up transistor-gating node and a pull-down transistor-gating node. The port control module sets the voltages of the pull-up transistor-gating node and the pull-down transistor-gating node.

This application claims the benefit of Taiwan application Serial No. 114103630, filed Jan. 24, 2025, the disclosure of which is incorporated by reference herein in its entirety.

### TECHNICAL FIELD

The present invention relates to a driver, and more particularly to a single-stage driver suitable for low-power applications.

### PRIOR ARTS

Mobile Industry Processor Interface (hereinafter, MIPI) is a specification defined for processor design widely applied for mobile devices such as mobile phones. In the MIPI architecture, the MIPI controller uses a physical layer transmitter (PHY layer transmitter) to transmit clock signals and data signals to a receiving circuit. The data signal transmitted by the MIPI transmitter can be transmitted through one or more data lanes, and the MIPI transmitter sets a port physical layer driver for each data lane.

Please refer to FIG. 1, which is a block diagram illustrating a MIPI port physical layer driver in the prior arts. The MIPI port physical layer driver 10 receives a driving enable-signal EN and a driver input signal inDAT in a digital form, switching between 0 and 1 from the MIPI controller. When the driving enable-signal EN is at a high logic-level H (EN=H), the MIPI port physical layer driver 10 generates a driver output signal outSIG in a voltage form according to the driver input signal inDAT. Alternatively, when the driving enable-signal EN is at a low logic-level L (EN=L), the MIPI port physical layer driver 10 stops generating the driver output signal outSIG generated according to the driver input signal inDAT. Thereafter, the driver output signal outSIG will be further transmitted to a MIPI receiver.

The MIPI port physical layer driver 10 includes a port control circuit 101, a low-dropout regulator (LDO) 103, a first-stage driving circuit (DRV1) 105, and a second-stage driving circuit (DRV2) 107. The first-stage driving circuit (DRV1) 105 includes a pull-up circuit upCKT1 and a pull-down circuit dnCKT1; and the second-stage driving circuit (DRV2) 107 includes a pull-up capacitor Cup, a pull-up circuit upCKT2, a pull-down capacitor Cdn, and a pull-down circuit dnCKT2.

The port control circuit 101 is electrically connected to the first-stage driving circuit (DRV1) 105 and the second-stage driving circuit (DRV2) 107. The low-dropout regulator (LDO) 103 is electrically connected to the first-stage driving circuit (DRV1) 105. In addition, the port control circuit 101, the pull-up capacitor Cup, the pull-down capacitor Cdn, the pull-up circuits upCKT1 and upCKT2, and the pull-down circuits dnCKT1 and dnCKT2 are all electrically connected to a driver output node NDₒᵤₜ. The pull-up circuit upCKT1 is electrically connected to a low supply voltage node Vddl (1.2V, for example), the pull-up circuit upCKT2 is electrically connected to a high supply voltage node Vddh (1.8V, for example), and both the pull-down circuits dnCKT1 and dnCKT2 are electrically connected to a ground voltage node Gnd.

For illustrative purposes, a signal line and a signal/voltage on this signal line are represented by the same symbol herein. For example, the symbol Vddh may indicate either a high supply voltage node or a high supply voltage according to the context.

The voltage of the driver output signal outSIG changes with the value of the driver input signal inDAT. When the value of the driver input signal inDAT is “0” (inDAT=“0”), the driver output signal outSIG generated by the MIPI port physical layer driver 10 at the driver output node NDₒᵤₜ is 0V. When the value of the driver input signal inDAT is “1” (inDAT=“1”), the driver output signal outSIG generated by the MIPI port physical layer driver 10 at the driver output node NDₒᵤₜ is 1.2V.

The port control circuit 101 receives the driver input signal inDAT from a MIPI controller; receives an input reference voltage Vref_in with a predetermined voltage value (1V, for example) and a high supply voltage Vddh (1.8V, for example); and receives the driver output signal outSIG from the driver output node NDₒᵤₜ. After receiving the high supply voltage Vddh (1.8V, for example) and a low-dropout reference voltage Vref_ldo (0.6V, for example), the low-dropout regulator (LDO) 103 first generates and transmits a low supply voltage Vddl (1.2V) to the first-stage driving circuit (DRV1) 105.

The port control circuit 101 generates control signals ctlSIG_pg1, ctlSIG_pg2, ctlSIG_ng1, and ctlSIG_ng2 in response to the change of the driver input signal inDAT. The port control circuit 101 transmits the control signal ctlSIG_pg1 to the pull-up circuit upCKT1 of the first-stage driving circuit (DRV1) 105; transmits the control signal ctlSIG_ng1 to the pull-down circuit dnCKT1 of the first-stage driving circuit (DRV1) 105; transmits the control signal ctlSIG_pg2 to the pull-up circuit upCKT2 and the pull-up capacitor Cup of the second-stage driving circuit (DRV2) 107; and transmits the control signal ctlSIG_ng2 to the pull-down circuit dnCKT2 and the pull-down capacitor Cdn of the second-stage driving circuit (DRV2) 107.

When the driver input signal inDAT is in a transient state changing from a low logic-level L to a high logic-level H (inDAT=L→H), the port control circuit 101 uses the control signal ctlSIG_pg2 to enable the pull-up circuit upCKT2. On the other hand, the port control circuit 101 uses the control signal ctlSIG_pg1 to disable the pull-up circuit upCKT1, uses the control signal ctlSIG_ng1 to disable the pull-down circuit dnCKT1, and uses the control signal ctlSIG_ng2 to disable the pull-down circuit dnCKT2.

When the driver input signal inDAT is in a stable state remaining at a high logic-level H, the port control circuit 101 uses the control signal ctlSIG_pg1 to enable the pull-up circuit upCKT1 to make the driver output signal outSIG remain at a low supply voltage Vddl (1.2V, for example). At this time, the port control circuit 101 uses the control signal ctlSIG_ng1 to disable the pull-down circuit dnCKT1, uses the control signal ctlSIG_pg2 to disable the pull-up circuit upCKT2, and uses the control signal ctlSIG_ng2 to disable the pull-down circuit dnCKT2.

When the driver input signal inDAT is in a transient state changing from a high logic-level H to a low logic-level L (inDAT=H→L), the port control circuit 101 uses the control signal ctlSIG_ng2 to enable the pull-down circuit dnCKT2. On the other hand, the port control circuit 101 uses the control signal ctlSIG_pg1 to disable the pull-up circuit upCKT1, uses the control signal ctlSIG_ng1 to disable the pull-down circuit dnCKT1, and uses the control signal ctlSIG_pg2 to disable the pull-up circuit upCKT2.

When the driver input signal inDAT is in a stable state remaining at a low logic-level L, the port control circuit 101 uses the control signal ctlSIG_ng1 to enable the pull-down circuit dnCKT1 to make the driver output signal outSIG remain at the ground voltage Gnd. At this time, the port control circuit 101 uses the control signal ctlSIG_pg1 to disable the pull-up circuit upCKT1, uses the control signal ctlSIG_pg2 to disable the pull-up circuit upCKT2, and uses the control signal ctlSIG_ng2 to disable the pull-down circuit dnCKT2.

As described above, in order to generate a driver output signal outSIG of 1.2V when the driver input signal inDAT is at a high logic-level H (inDAT=“H”), the MIPI port physical layer driver 10 needs two driving circuits, that is, the first-stage driving circuit (DRV1) 105 and the second-stage driving circuit (DRV2) 107. The first-stage driving circuit (DRV1) 105 is used to generate the driver output signal outSIG of 1.2V. The second-stage driving circuit (DRV2) 107 is used to adjust the slew rate of the driver output signal outSIG during the transient state of the driver input signal inDAT (for example, the driver input signal inDAT changing from a low logic-level L to a high logic-level H (inDAT=“L→H”), or the transient state of the driver input signal inDAT changing from a high logic-level H to a low logic-level L (inDAT=“H→L”)).

It can be seen from FIG. 1 that the conventional MIPI port physical layer driver 10 has at least the following problems. First, it needs to receive two reference voltages (the input reference voltage Vref_in and the low-dropout reference voltage Vref_ldo) from the outside. Second, an additional low-dropout regulator 103 is required to provide the low supply voltage Vddl. Third, an error amplifier is needed in the low-dropout regulator 103, and an operational amplifier (hereinafter, OP) used as a comparator is needed in the port control circuit 101. Therefore, the circuit design of the conventional MIPI port physical layer driver 10 is much complicated.

### SUMMARY OF THE INVENTION

The present disclosure is directed to a driver implemented by a single-stage driving circuit. Instead of the low-dropout regulator, the driver of the present disclosure only needs one comparison circuit. The circuit area is small, and it is applicable to low-power applications.

According to an aspect of the present invention, a driver is provided. The driver includes a switching-signal generation circuit, a comparison circuit, a driving circuit, and a port control module. The switching-signal generation circuit generates a positive pull-up switching-signal, a negative pull-up switching-signal, a positive pull-down switching-signal, and a negative pull-down switching-signal according to a driving enable-signal and a driver input signal. The comparison circuit is electrically connected to a first constant voltage node and a second constant voltage node. The comparison circuit includes a non-inverting input-terminal, an inverting input-terminal, a non-inverting output-terminal, and an inverting output-terminal. The non-inverting input-terminal is electrically connected to a driver output node of the driver. The inverting input-terminal receives a reference voltage. The reference voltage is higher than the voltage at the second constant voltage node and lower than the voltage at the first constant voltage node. The inverting output-terminal is electrically connected to a pull-up transistor-gating node. The driving circuit includes a pull-up circuit and a pull-down circuit. The pull-up circuit is electrically connected to the switching-signal generation circuit and the comparison circuit. The pull-up circuit selectively adjusts the voltage of the driver output node according to the positive pull-up switching-signal and a voltage of the pull-up transistor-gating node. The pull-down circuit is electrically connected to the switching-signal generation circuit. The pull-down circuit selectively adjusts the voltage of the driver output node according to the negative pull-down switching-signal and a voltage of a pull-down transistor-gating node. The port control module is electrically connected to the switching-signal generation circuit, the comparison circuit, and the driving circuit. The port control module sets the voltage of the pull-up transistor-gating node and the voltage of the pull-down transistor-gating node according to the positive pull-up switching-signal, the negative pull-up switching-signal, the positive pull-down switching-signal, and the negative pull-down switching-signal.

For a better understanding of the above and other aspects of the present invention, embodiments are specifically described in detail with reference to the accompanying drawings as follows:

### BRIEF DESCRIPTION OF THE DRAWINGS

FIG. 1 (prior art) is a block diagram of a MIPI port physical layer driver in the prior arts.

FIG. 2 is a block diagram of a driver portDRV according to the present disclosure.

FIG. 3 is a schematic diagram illustrating a logic circuit of the switching-signal generation circuit swGenCKT according to the present disclosure.

FIG. 4 is a schematic diagram illustrating internal components and related signals of the port control module portCtrlMDL according to the present disclosure.

FIG. 5 is a schematic diagram illustrating internal components and related signals of the comparison circuit cfCKT according to the present disclosure.

FIG. 6 is a schematic diagram illustrating internal components and related signals of the driving circuit DRV according to the present disclosure.

FIG. 7 is a schematic diagram illustrating internal components and related signals of the compensation circuit compCKT according to the present disclosure.

FIG. 8 is a circuit diagram of the driver portDRV according to the present disclosure.

FIG. 9 is a schematic diagram showing circuit behavior of the driver portDRV according to the present disclosure when the driving enable-signal EN is at a low logic-level L (EN=L).

FIG. 10 is a schematic state diagram showing how the port control module portCtrlMDL of the present disclosure controls circuit behavior of the driver portDRV in response to the change of the driver input signal inDAT when the driving enable-signal EN is at a high logic-level H (EN=H).

FIG. 11 is a schematic diagram showing the circuit behavior of the driver portDRV during the rising-transition phase PH1 according to the present disclosure.

FIG. 12 is a schematic diagram showing the circuit behavior of the driver portDRV during the high-level stable phase PH2 according to the present disclosure.

FIG. 13 is a schematic diagram showing the circuit behavior of the driver portDRV during the falling-transition phase PH3 according to the present disclosure.

FIG. 14 is a schematic diagram showing the circuit behavior of the driver portDRV during the low-level stable phase PH4 according to the present disclosure.

FIG. 15 is a waveform diagram showing the signals on the internal nodes of the driver portDRV of the present disclosure in response to the change of the driver input signal inDAT when the driving enable-signal EN is at a high logic-level H (EN=H) and the external enable-signal IQ_extEN for the additional current-path(s) add_curPATH is set to a low logic-level L (IQ_extEN=L) to disable the additional current-path add_curPATH.

FIG. 16 is a waveform diagram showing the signals on the internal nodes of the driver portDRV of the present disclosure in response to the change of the driver input signal inDAT when the driving enable-signal EN is at a high logic-level H (EN=H) and the external enable-signal IQ_extEN for the additional current-path(s) add_curPATH is set to a high logic-level H (IQ_extEN=H) to enable the additional current-path add_curPATH.

FIG. 17 is a schematic diagram illustrating a driver portDRV with a transistor-path output impedance Rout_ts and a capacitor-path output impedance Rout_cp.

FIG. 18A is a schematic diagram for calculating the equivalent output impedance Rout_eq of the driver portDRV with the transistor-path output impedance Rout_ts and the capacitor-path output impedance Rout_cp added, wherein the pull-up path is selected in the rising-transition phase PH1 and the high-level stable phase PH2.

FIG. 18B is a schematic diagram for calculating the equivalent output impedance Rout_eq of the driver portDRV with the transistor-path output impedance Rout_ts and the capacitor-path output impedance Rout_cp added, wherein the pull-down path is selected in the falling-transition phase PH3 and the low-level stable phase PH4.

FIG. 19 is a schematic diagram illustrating that plural pull-up transistors upPM[1]~upPM[4], plural pull-down transistors dnNM[1]~dnNM[4], and plural transistor-path output impedances Rout_ts[1]~Rout_ts[4] are provided and arranged in parallel in a driver portDRV.

FIG. 20 is a schematic diagram illustrating that compensation current-paths comp_curPATH[1]~comp_curPATH[4] and additional current-paths add_curPATH[1]~add_curPATH[4] are set in parallel in the driver portDRV of FIG. 19.

FIG. 21 is a schematic diagram illustrating that in the driver portDRV according to the present disclosure, the combination of the comparison circuit cfCKT, the pull-up transistor upPM, and the compensation circuit compCKT functions as a low-dropout regulator LDO.

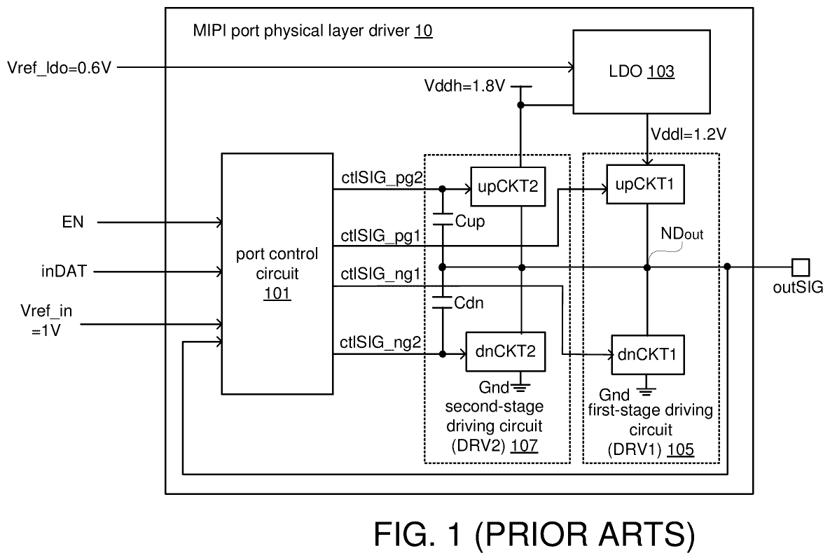

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

In order to improve the deficiencies of the conventional MIPI port physical layer driver, the present disclosure proposes the following embodiments of the physical layer driver. The driver portDRV of the present disclosure can be applied to the MIPI port physical layer driver or other types of applications. As disclosed in the following embodiments, the driver portDRV of the present disclosure need not additionally set up a low-dropout regulator (LDO). Instead, only one operational amplifier and a single-stage driving circuit are set up, and only one reference voltage Vref (1.2V, for example) is required.

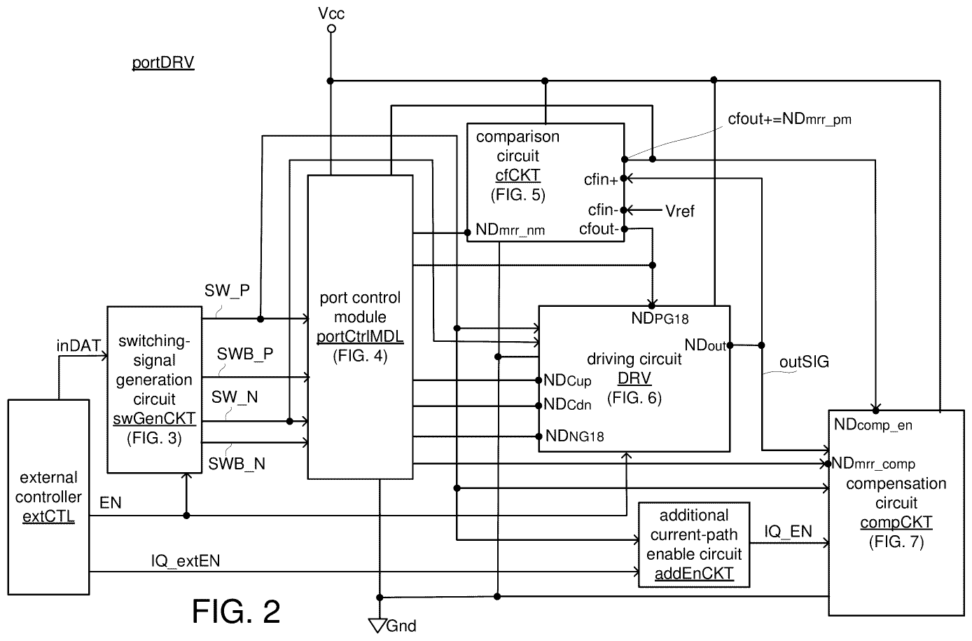

Please refer to FIG. 2, which is a block diagram of a driver portDRV according to the present disclosure. The driver portDRV includes a switching-signal generation circuit swGenCKT, a port control module portCtrlMDL, a comparison circuit cfCKT, a driving circuit DRV, and a compensation circuit compCKT. Signals related to the switching-signal generation circuit swGenCKT, the port control module portCtrlMDL, the comparison circuit cfCKT, the driving circuit DRV, and the compensation circuit compCKT will be described in sequence.

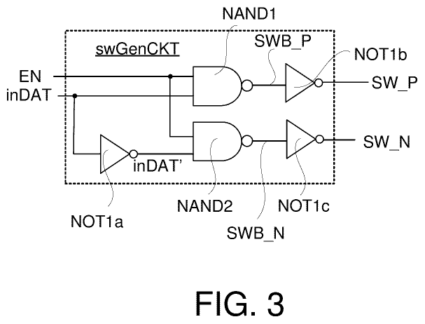

The switching-signal generation circuit swGenCKT is electrically connected to an external controller extCTL (a MIPI controller, for example), the port control module portCtrlMDL, the driving circuit DRV, and the compensation circuit compCKT. After receiving a driving enable-signal EN and a driver input signal inDAT from the external controller extCTL, the switching-signal generation circuit swGenCKT generates a positive pull-up switching-signal SW_P, a negative pull-up switching-signal SWB_P, a positive pull-down switching-signal SW_N, and a negative pull-down switching-signal SWB_N according to the logic-levels of the driving enable-signal EN and the driver input signal inDAT. The details related to the switching-signal generation circuit swGenCKT will be illustrated in FIG. 3.

The port control module portCtrlMDL is electrically connected to the supply voltage node Vcc, the ground voltage node Gnd, and the switching-signal generation circuit swGenCKT. The port control module portCtrlMDL is further electrically connected to the comparison circuit cfCKT through an NMOS-current-mirror bias node ND_{mrr_nm}, a PMOS-current-mirror bias node ND_{mrr_pm}, and a pull-up transistor-gating node ND_{PG18}. The port control module portCtrlMDL is further electrically connected to the driving circuit DRV through a pull-up capacitor node ND_{Cup}, a pull-down capacitor node ND_{Cdn}, a pull-down transistor-gating node ND_{NG18}, and the pull-up transistor-gating node ND_{PG18}. The port control module portCtrlMDL is further electrically connected to the compensation circuit compCKT, through a compensation bias node ND_{mrr_comp}. Each of the supply voltage node Vcc and the ground voltage node Gnd has a constant voltage value. For example, the voltage value of the supply voltage node Vcc is 1.8V, and the voltage value of the ground voltage node Gnd is 0V.

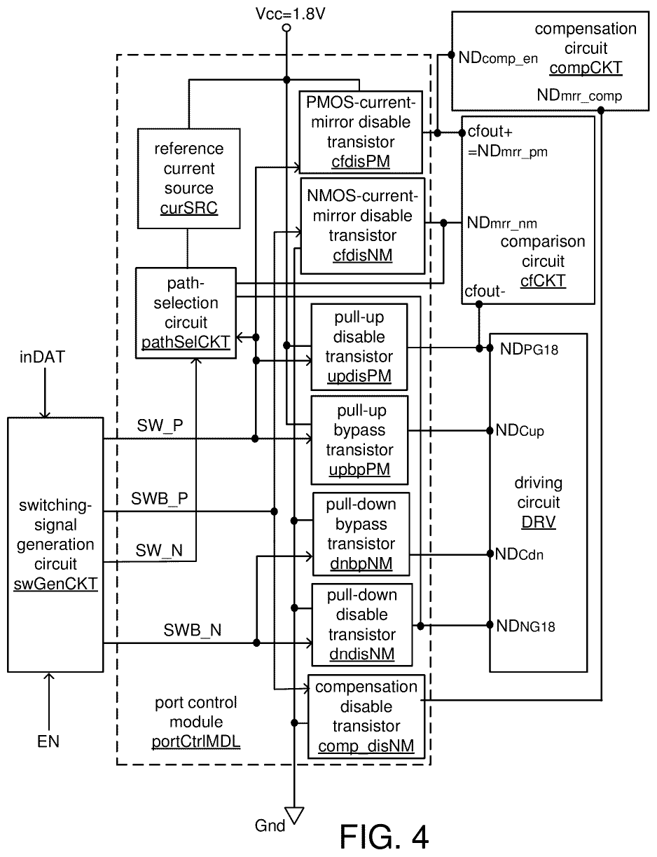

The port control module portCtrlMDL receives the positive pull-up switching-signal SW_P, the negative pull-up switching-signal SWB_P, the positive pull-down switching-signal SW_N, and the negative pull-down switching-signal SWB_N from the switching-signal generation circuit swGenCKT to generate signals related to the comparison circuit cfCKT, the driving circuit DRV, and the compensation circuit compCKT. The internal components and related signals of the port control module portCtrlMDL will be illustrated in FIG. 4.

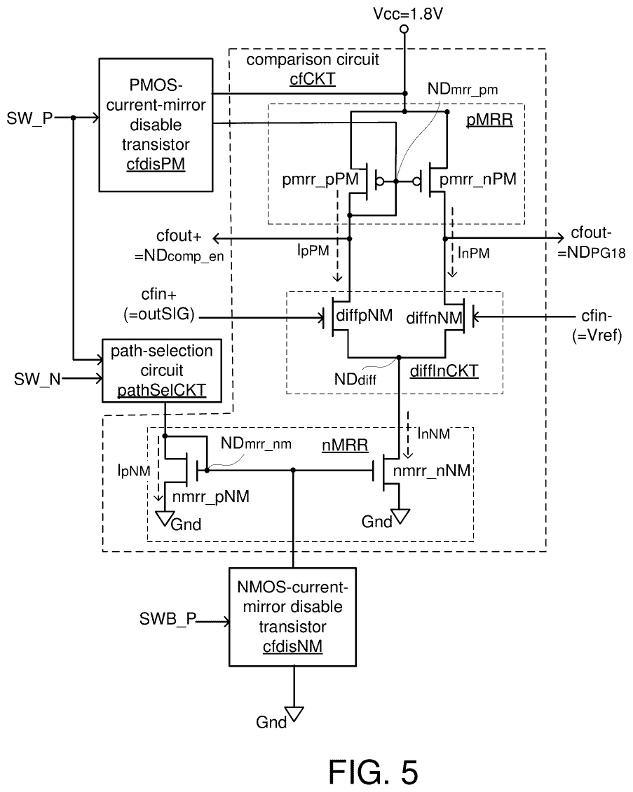

The comparison circuit cfCKT is electrically connected to the supply voltage node Vcc, the ground voltage node Gnd, the port control module portCtrlMDL, the driving circuit DRV, and the compensation circuit compCKT. The comparison circuit cfCKT has an inverting output-terminal cfout−, a non-inverting output-terminal cfout+, an inverting input-terminal cfin-, and a non-inverting input-terminal cfin+. The inverting output-terminal cfout− of the comparison circuit cfCKT is electrically connected to the pull-up transistor-gating node ND_{PG18} of the driving circuit DRV. The non-inverting output-terminal cfout+ is electrically connected to a compensation enable node ND_{comp_en} of the comparison circuit cfCKT. The comparison circuit cfCKT receives the reference voltage Vref (1.2V, for example) having a constant voltage value through the inverting input-terminal cfin−, and receives the driver output signal outSIG, generated by the driving circuit DRV at the driver output node NDₒᵤₜ, through the non-inverting input-terminal cfin+. The internal components and related signals of the comparison circuit cfCKT will be illustrated in FIG. 5.

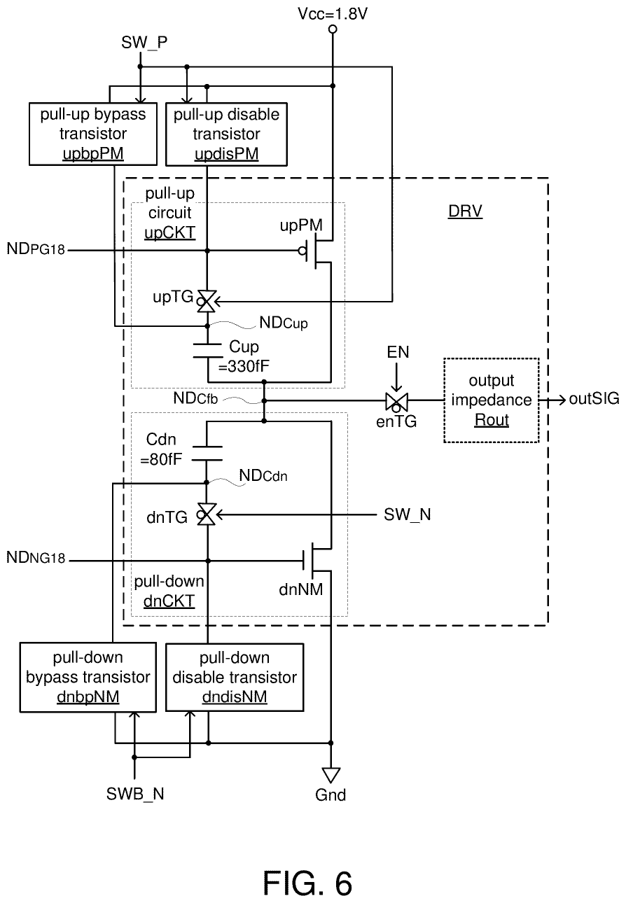

The driving circuit DRV is electrically connected to the supply voltage node Vcc, the ground voltage node Gnd, and the switching-signal generation circuit swGenCKT. The driving circuit DRV is further electrically connected to the port control module portCtrlMDL through the pull-up capacitor node ND_{Cup}, the pull-down capacitor node ND_{Cdn}, the pull-up transistor-gating node ND_{PG18}, and the pull-down transistor-gating node ND_{NG18}. The driving circuit DRV is further electrically connected to the compensation circuit compCKT through the driver output node NDₒᵤₜ. According to concepts of the present disclosure, the internal components of the driving circuit DRV change the driver output signal outSIG according to the driving enable-signal EN transmitted from the external controller extCTL, the voltage of the inverting output-terminal cfout− of the comparison circuit cfCKT (equivalent to the pull-up transistor-gating node ND_{PG18}), the voltage of the pull-down transistor-gating node ND_{NG18} set by the port control module portCtrlMDL, and the positive pull-up switching-signal SW_P and the positive pull-down switching-signal SW_N transmitted from the switching-signal generation circuit swGenCKT. Then, the driving circuit DRV transmits the driver output signal outSIG to the non-inverting input-terminal cfin+ of the comparison circuit cfCKT. The internal components and related signals of the driving circuit DRV will be illustrated in FIG. 6.

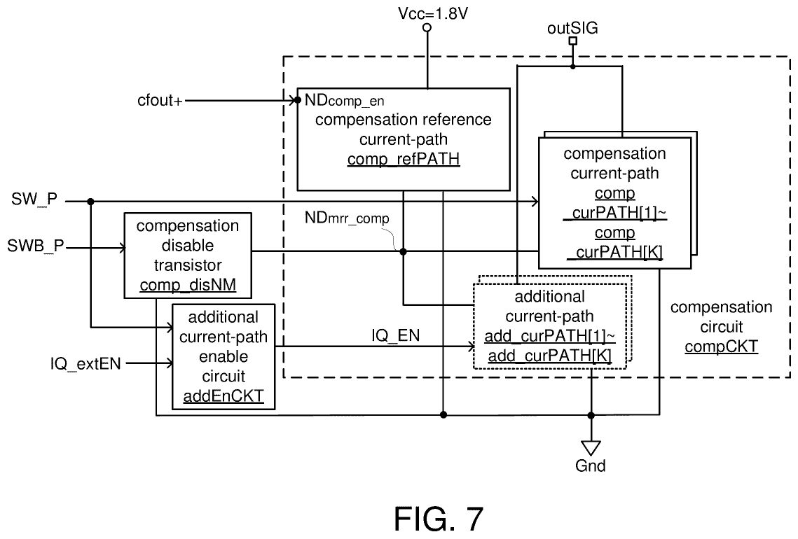

The compensation circuit compCKT is electrically connected to the supply voltage node Vcc and the ground voltage node Gnd. The compensation enable node ND_{comp_en} of the compensation circuit compCKT is electrically connected to the non-inverting output-terminal cfout+ of the comparison circuit cfCKT Therefore, the voltage of the non-inverting output-terminal cfout+ of the comparison circuit cfCKT is equivalent to the voltage of the compensation enable node ND_{comp_en}. In addition, the compensation circuit compCKT receives the positive pull-up switching-signal SW_P from the switching-signal generation circuit swGenCKT, and receives the driver output signal outSIG from the driver output node NDₒᵤₜ of the driving circuit DRV. The internal components and related signals of the compensation circuit compCKT will be illustrated in FIG. 7.

An additional current-path enable circuit addEnCKT is electrically connected to the external controller extCTL, the switching-signal generation circuit swGenCKT, and the compensation circuit compCKT. One input terminal of the additional current-path enable circuit addEnCKT receives the external enable-signal IQ_extEN for the additional current-path(s) from the external controller extCTL, and the other input terminal of the additional current-path enable circuit addEnCKT receives the positive pull-up switching-signal SW_P from the switching-signal generation circuit swGenCKT. The additional current-path enable circuit addEnCKT generates and transmits an additional current-path enable-signal IQ_EN through an output terminal of the additional current-path enable circuit addEnCKT to the compensation circuit compCKT.

Please refer to FIG. 3, which is a schematic diagram illustrating a logic circuit of the switching-signal generation circuit swGenCKT according to the present disclosure. In FIG. 3, the switching-signal generation circuit swGenCKT includes NAND gates NAND1, NAND2, and NOT gates NOT1a, NOT1b, NOT1c. In actual applications, the implementation of the switching-signal generation circuit swGenCKT is not limited to the example in FIG. 3.

One input terminal of the NAND gate NAND1 receives the driving enable-signal EN, and the other input terminal of the NAND gate NAND1 receives the driver input signal inDAT. The output terminal of the NAND gate NAND1 is defined as the negative pull-up switching-signal SWB_P. The NOT gate NOT1b generates the positive pull-up switching-signal SW_P after receiving the negative pull-up switching-signal SWB_P through the input terminal thereof. The NOT gate NOT1a generates the inverted driver input signal inDAT′ after receiving the driver input signal inDAT through the input terminal thereof. One input terminal of the NAND gate NAND2 receives the driving enable-signal EN, and the other input terminal receives the inverted driver input signal inDAT′ output by the NOT gate NOT1a. The output terminal of the NAND gate NAND2 is defined as the negative pull-down switching-signal SWB_N. The NOT gate NOT1c generates the positive pull-down switching-signal SW_N after receiving the negative pull-down switching-signal SWB_N through the input terminal thereof.

In FIG. 3, the logic-levels of the positive pull-up switching-signal SW_P, the negative pull-up switching-signal SWB_P, the positive pull-down switching-signal SW_N, and the negative pull-down switching-signal SWB_N in response to the logic-levels of the driving enable-signal EN and the driver input signal inDAT are shown in Table 1.

TABLE 1

| | | | positive | negative | positive | negative |
|---|---|---|---|---|---|---|
| | | | pull-up | pull-up | pull-down | pull-down |
| driving | driver input | inverted driver | switching- | switching- | switching- | switching- |
| enable-signal | signal | input signal | signal | signal | signal | signal |
| EN | inDAT | inDAT′ | SW_P | SWB_P | SW_N | SWB_N |
| driving | driver input | inverted driver | low | high | low | high |
| enable-signal | signal inDAT | input signal | logic-level L | logic-level H | logic-level L | logic-level H |
| EN at low | at high | inDAT′ at low | | | | |
| logic-level L | logic-level H | logic-level L | | | | |
| (EN = L) | (inDAT = H) | (inDAT′ = L) | | | | |
| | driver input | inverted driver | | | | |
| | signal inDAT | input signal | | | | |
| | at low | inDAT′ at high | | | | |
| | logic-level L | logic-level H | | | | |
| | (inDAT = L) | (inDAT′ = H) | | | | |
| driving | driver input | inverted driver | high | low | low | high |
| enable-signal | signal inDAT | input signal | logic-level H | logic-level L | logic-level L | logic-level H |
| EN at high | at high | inDAT′ at low | | | | |
| logic-level H | logic-level H | logic-level L | | | | |
| (EN = H) | (inDAT = H) | (inDAT′ = L) | | | | |
| | driver input | inverted driver | low | high | high | low |
| | signal inDAT | input signal | logic-level L | logic-level H | logic-level H | logic-level L |
| | at low | inDAT′ at high | | | | |
| | logic-level L | logic-level H | | | | |
| | (inDAT = L) | (inDAT′ = H) | | | | |

It is obtained from Table 1 that whether the logic-level of the driver input signal inDAT affects the logic-levels of the positive pull-up switching-signal SW_P, the negative pull-up switching-signal SWB_P, the positive pull-down switching-signal SW_N, and the negative pull-down switching-signal SWB_N or not depends on the logic-level of the driving enable-signal EN.

When the driving enable-signal EN is at a low logic-level L (EN=L), the logic-level of the driver input signal inDAT does not affect the logic-levels of the positive pull-up switching-signal SW_P, the negative pull-up switching-signal SWB_P, the positive pull-down switching-signal SW_N, and the negative pull-down switching-signal SWB_N. More specifically, when the driving enable-signal EN is at a low logic-level L (EN=L), no matter how the logic-level of the driver input signal inDAT changes, both the positive pull-up switching-signal SW_P and the positive pull-down switching-signal SW_N remain at a low logic-level L (SW_P=SW_N=L); and both the negative pull-up switching-signal SWB_P and the negative pull-down switching-signal SWB_N remain at a high logic-level H (SWB_P=SWB_N=H).

Conversely, when the driving enable-signal EN is at a high logic-level H (EN=H), the logic-levels of the positive pull-up switching-signal SW_P and the negative pull-down switching-signal SWB_N are equivalent to the logic-level of the driver input signal inDAT (SW_P=SWB_N=inDAT). And, the logic-levels of the negative pull-up switching-signal SWB_P and the positive pull-down switching-signal SW_N are equivalent to the logic-level of the inverted driver input signal inDAT′ (SWB_P=SW_N=inDAT′).

Please refer to FIG. 4, which is a schematic diagram illustrating internal components and related signals of the port control module portCtrlMDL according to the present disclosure. The port control module portCtrlMDL includes a reference current source curSRC, a path-selection circuit pathSelCKT, a PMOS-current-mirror disable transistor cfdisPM, an NMOS-current-mirror disable transistor cfdisNM, a pull-up disable transistor updisPM, a pull-up bypass transistor upbpPM, a pull-down disable transistor dndisNM, a pull-down bypass transistor dnbpNM, and a compensation disable transistor comp_disNM.

The reference current source curSRC is electrically connected to the supply voltage node Vcc and the path-selection circuit pathSelCKT. The reference current source curSRC is used to provide a stable reference current Iref (10 μA, for example).

The path-selection circuit pathSelCKT is electrically connected to the switching-signal generation circuit swGenCKT, the comparison circuit cfCKT, and the pull-down transistor-gating node ND_{NG18}. The path-selection circuit pathSelCKT receives the positive pull-up switching-signal SW_P and the positive pull-down switching-signal SW_N from the switching-signal generation circuit swGenCKT.

The PMOS-current-mirror disable transistor cfdisPM is electrically connected to the supply voltage node Vcc, the switching-signal generation circuit swGenCKT, and the PMOS-current-mirror bias node ND_{mrr_pm}. The PMOS-current-mirror disable transistor cfdisPM is further electrically connected to the compensation circuit compCKT and a PMOS current-mirror pMRR through the PMOS-current-mirror bias node ND_{mrr_pm}. The PMOS-current-mirror disable transistor cfdisPM receives the positive pull-up switching-signal SW_P from the switching-signal generation circuit swGenCKT. When the PMOS-current-mirror disable transistor cfdisPM is turned on due to the logic-level of the positive pull-up switching-signal SW_P, the PMOS-current-mirror disable transistor cfdisPM conducts the supply voltage Vcc to the PMOS-current-mirror bias node ND_{mrr_pm}. That is, ND_{mrr_pm}=Vcc. Conversely, when the PMOS-current-mirror disable transistor cfdisPM is turned off due to the logic-level of the positive pull-up switching-signal SW_P, the PMOS-current-mirror disable transistor cfdisPM does not affect the voltage of the PMOS-current-mirror bias node ND_{mrr_pm}.

The NMOS-current-mirror disable transistor cfdisNM is electrically connected to the ground voltage node Gnd, the switching-signal generation circuit swGenCKT, and the NMOS-current-mirror bias node ND_{mrr_nm}. The NMOS-current-mirror disable transistor cfdisNM is further electrically connected to the NMOS current-mirror nMRR through the NMOS-current-mirror bias node ND_{mrr_nm}. The NMOS-current-mirror disable transistor cfdisNM receives the negative pull-up switching-signal SWB_P from the switching-signal generation circuit swGenCKT. When the NMOS-current-mirror disable transistor cfdisNM is turned on due to the logic-level of the negative pull-up switching-signal SWB_P, the NMOS-current-mirror disable transistor cfdisNM conducts the ground voltage Gnd to the NMOS-current-mirror bias node ND_{mrr_nm}. That is, ND_{mrr_nm}=Gnd. Conversely, when the NMOS-current-mirror disable transistor cfdisNM is turned off due to the logic-level of the negative pull-up switching-signal SWB_P the NMOS-current-mirror disable transistor cfdisNM does not affect the voltage of the NMOS-current-mirror bias node ND_{mrr_nm}.

The pull-up disable transistor updisPM is electrically connected to the supply voltage node Vcc, the switching-signal generation circuit swGenCKT, and the pull-up transistor-gating node ND_{PG18}. The pull-up disable transistor updisPM is electrically connected to the driving circuit DRV through the pull-up transistor-gating node ND_{PG18}. The pull-up disable transistor updisPM receives the positive pull-up switching-signal SW_P from the switching-signal generation circuit swGenCKT. When the pull-up disable transistor updisPM is turned on due to the logic-level of the positive pull-up switching-signal SW_P, the pull-up disable transistor updisPM conducts the supply voltage Vcc to the pull-up transistor-gating node ND_{PG18}. That is, ND_{PG18}=Vcc. Conversely, when the pull-up disable transistor updisPM is turned off due to the logic-level of the positive pull-up switching-signal SW_P, the pull-up disable transistor updisPM does not affect the voltage of the pull-up transistor-gating node ND_{PG18}.

The pull-up bypass transistor upbpPM is electrically connected to the supply voltage node Vcc, the switching-signal generation circuit swGenCKT, and the pull-up capacitor node ND_{Cup}. The pull-up bypass transistor upbpPM is electrically connected to the driving circuit DRV through the pull-up capacitor node ND_{Cup}. The pull-up bypass transistor upbpPM receives the positive pull-up switching-signal SW_P from the switching-signal generation circuit swGenCKT. When the pull-up bypass transistor upbpPM is turned on due to the logic-level of the positive pull-up switching-signal SW_P, the pull-up bypass transistor upbpPM conducts the supply voltage Vcc to the pull-up capacitor node ND_{Cup}. That is, ND_{Cup}=Vcc. Conversely, when the pull-up bypass transistor upbpPM is turned off due to the logic-level of the positive pull-up switching-signal SW_P, the pull-up bypass transistor upbpPM does not affect the voltage of the pull-up capacitor node ND_{Cup}.

The pull-down bypass transistor dnbpNM is electrically connected to the ground voltage node Gnd, the switching-signal generation circuit swGenCKT, and the pull-down capacitor node ND_{Cdn}. The pull-down bypass transistor dnbpNM is electrically connected to the driving circuit DRV through the pull-down capacitor node ND_{Cdn}. The pull-down bypass transistor dnbpNM receives the negative pull-down switching-signal SWB_N from the switching-signal generation circuit swGenCKT. When the pull-down bypass transistor dnbpNM is turned on due to the logic-level of the negative pull-down switching-signal SWB_N, the pull-down bypass transistor dnbpNM conducts the ground voltage Gnd to the pull-down capacitor node ND_{Cdn}. That is, ND_{Cdn}=Gnd. When the pull-down bypass transistor dnbpNM is turned off due to the logic-level of the negative pull-down switching-signal SWB_N, the pull-down bypass transistor dnbpNM does not affect the voltage of the pull-down capacitor node ND_{Cdn}.

The pull-down disable transistor dndisNM is electrically connected to the ground voltage node Gnd, the switching-signal generation circuit swGenCKT, and the pull-down transistor-gating node ND_{NG18}. The pull-down disable transistor dndisNM is electrically connected to the driving circuit DRV through the pull-down transistor-gating node ND_{NG18}. The pull-down disable transistor dndisNM receives the negative pull-down switching-signal SWB_N from the switching-signal generation circuit swGenCKT. When the pull-down disable transistor dndisNM is turned on due to the logic-level of the negative pull-down switching-signal SWB_N, the pull-down disable transistor dndisNM conducts the ground voltage Gnd to the pull-down transistor-gating node ND_{NG18}. That is, ND_{NG18}=Gnd. When the pull-down disable transistor dndisNM is turned off due to the logic-level of the negative pull-down switching-signal SWB_N, the pull-down disable transistor dndisNM does not affect the voltage of the pull-down transistor-gating node ND_{NG18}.

The compensation disable transistor comp_disNM is electrically connected to the ground voltage node Gnd, the switching-signal generation circuit swGenCKT, and the compensation bias node ND_{mrr_comp}. The compensation disable transistor comp_disNM is electrically connected to the compensation circuit compCKT through the compensation bias node ND_{mrr_comp}. The compensation disable transistor comp_disNM receives the negative pull-up switching-signal SWB_P from the switching-signal generation circuit swGenCKT. When the compensation disable transistor comp_disNM is turned on due to the logic-level of the negative pull-up switching-signal SWB_P, the compensation disable transistor comp_disNM conducts the ground voltage Gnd to the compensation bias node ND_{mrr_comp}. That is, ND_{mrr_comp}=Gnd. When the compensation disable transistor comp_disNM is turned off due to the logic-level of the negative pull-up switching-signal SWB_P, the compensation disable transistor comp_disNM does not affect the voltage of the compensation bias node ND_{mrr_comp}.

Please refer to FIG. 5, which is a schematic diagram illustrating internal components and related signals of the comparison circuit cfCKT according to the present disclosure. According to concepts of the present disclosure, the comparison circuit cfCKT is a single-stage CMOS operational amplifier (single-stage OP AMP).

The comparison circuit cfCKT includes a PMOS current-mirror pMRR, an NMOS current-mirror nMRR, and a differential input circuit difflnCKT. The PMOS current-mirror pMRR is electrically connected to the PMOS-current-mirror disable transistor cfdisPM and the differential input circuit difflnCKT. The NMOS current-mirror nMRR is electrically connected to the NMOS-current-mirror disable transistor cfdisNM, the differential input circuit difflnCKT, and the path-selection circuit pathSelCKT.

The PMOS current-mirror pMRR further includes a positive PMOS-current-mirror transistor pmrr_pPM and a negative PMOS-current-mirror transistor pmrr_nPM. The differential input circuit difflnCKT further includes a positive differential-input transistor diffpNM and a negative differential-input transistor diffnNM. The NMOS current-mirror nMRR further includes a positive NMOS-current-mirror transistor nmrr_pNM and a negative NMOS-current-mirror transistor nmrr_nNM. Among these transistors, the positive PMOS-current-mirror transistor pmrr_pPM and the negative PMOS-current-mirror transistor pmrr_nPM are PMOS transistors; and the positive differential-input transistor diffpNM, the negative differential-input transistor diffnNM, the positive NMOS-current-mirror transistor nmrr_pNM, and the negative NMOS-current-mirror transistor nmrr_nNM are NMOS transistors.

In the positive PMOS-current-mirror transistor pmrr_pPM, the source terminal is electrically connected to the supply voltage node Vcc, the gate terminal is electrically connected to the PMOS-current-mirror bias node ND_{mrr_pm}, and the drain terminal is electrically connected to the non-inverting output-terminal cfout+ of the comparison circuit cfCKT. On the other hand, in the negative PMOS-current-mirror transistor pmrr_nPM, the source terminal is electrically connected to the supply voltage node Vcc, the gate terminal is electrically connected to the PMOS-current-mirror bias node ND_{mrr_pm}, and the drain terminal is electrically connected to the inverting output-terminal cfout− of the comparison circuit cfCKT. Therefore, the ON/OFF states of both the positive PMOS-current-mirror transistor pmrr_pPM and the negative PMOS-current-mirror transistor pmrr_nPM depend on the voltage of the PMOS-current-mirror bias node ND_{mrr_pm}. In addition, the gate terminal and the drain terminal of the positive PMOS-current-mirror transistor pmrr_pPM are connected to each other. Therefore, the non-inverting output-terminal cfout+ of the comparison circuit cfCKT is equivalent to the voltage of the PMOS-current-mirror bias node ND_{mrr_pm}.

The PMOS-current-mirror disable transistor cfdisPM is electrically connected to the switching-signal generation circuit swGenCKT, the supply voltage node Vcc, and the PMOS-current-mirror bias node ND_{mrr_pm}. The PMOS-current-mirror disable transistor cfdisPM receives the positive pull-up switching-signal SW_P from the switching-signal generation circuit swGenCKT. The PMOS-current-mirror disable transistor cfdisPM is selectively turned on according to the logic-level of the positive pull-up switching-signal SW_P.

When the PMOS-current-mirror disable transistor cfdisPM is turned on, the PMOS-current-mirror disable transistor cfdisPM conducts the supply voltage Vcc to the PMOS-current-mirror bias node ND_{mrr_pm}. That is, ND_{mrr_pm}=Vcc. Thus, the positive PMOS-current-mirror transistor pmrr_pPM and the negative PMOS-current-mirror transistor pmrr_nPM are turned off because their gate terminals receive the supply voltage Vcc. Conversely, when the PMOS-current-mirror disable transistor cfdisPM is turned off, the PMOS-current-mirror disable transistor cfdisPM does not affect the voltage of the PMOS-current-mirror bias node ND_{mrr_pm}, and the ON/OFF states of the positive PMOS-current-mirror transistor pmrr_pPM and the negative PMOS-current-mirror transistor pmrr_nPM are not affected either.

In the positive differential-input transistor diffpNM of the differential input circuit difflnCKT, the drain terminal is electrically connected to the PMOS-current-mirror bias node ND_{mrr_pm}, and the gate terminal is equivalent to the non-inverting input-terminal cfin+ of the comparison circuit cfCKT. On the other hand, in the negative differential-input transistor diffnNM of the differential input circuit difflnCKT, the drain terminal is electrically connected to the inverting output-terminal cfout− of the comparison circuit cfCKT, and the gate terminal is equivalent to the inverting input-terminal cfin− of the comparison circuit cfCKT. The source terminal of the positive differential-input transistor diffpNM and the source terminal of the negative differential-input transistor diffnNM are electrically connected to the NMOS current-mirror nMRR through a differential node ND_{diff}. Therefore, whether the positive differential-input transistor diffpNM is turned on or off depends on the voltage of the non-inverting input-terminal cfin+ of the comparison circuit cfCKT, and whether the negative differential-input transistor diffnNM is turned on or off depends on the voltage of the inverting input-terminal cfin− of the comparison circuit cfCKT.

According to concepts of the present disclosure, the non-inverting input-terminal cfin+ of the comparison circuit cfCKT is electrically connected to the driver output node NDₒᵤₜ, and the inverting input-terminal cfin− of the comparison circuit cfCKT is used to receive the reference voltage Vref. Therefore, the voltage of the non-inverting input-terminal cfin+ of the comparison circuit cfCKT is equivalent to the voltage of the driver output signal outSIG. It is derived that whether the positive differential-input transistor diffpNM is turned on or off depends on the voltage of the driver output signal outSIG.

In the positive NMOS-current-mirror transistor nmrr_pNM, the drain terminal and the gate terminal are electrically connected to the NMOS-current-mirror bias node ND_{mrr_nm}, and the source terminal is electrically connected to the ground voltage node Gnd. On the other hand, in the negative NMOS-current-mirror transistor nmrr_nNM, the drain terminal is electrically connected to the differential node ND_{diff}, the gate terminal is electrically connected to the NMOS-current-mirror bias node ND_{mrr_nm}, and the source terminal is electrically connected to the ground voltage node Gnd. Therefore, whether the positive NMOS-current-mirror transistor nmrr_pNM and the negative NMOS-current-mirror transistor nmrr_nNM are turned on or off depends on the voltage of the NMOS-current-mirror bias node ND_{mrr_nm}. In addition, the voltage of the NMOS-current-mirror bias node ND_{mrr_nm} changes with the ON/OFF states of the path-selection circuit pathSelCKT and the NMOS-current-mirror disable transistor cfdisNM.

The path-selection circuit pathSelCKT is electrically connected to the NMOS-current-mirror bias node ND_{mrr_nm}. The path-selection circuit pathSelCKT receives the positive pull-up switching-signal SW_P and the positive pull-down switching-signal SW_N. When the path-selection circuit pathSelCKT is turned on, the path-selection circuit pathSelCKT conducts the supply voltage Vcc to the NMOS-current-mirror bias node ND_{mrr_nm}, thereby turning on the positive NMOS-current-mirror transistor nmrr_pNM and the negative NMOS-current-mirror transistor nmrr_nNM. Conversely, when the path-selection circuit pathSelCKT is turned off, the path-selection circuit pathSelCKT does not affect the voltage of the NMOS-current-mirror bias node ND_{mrr_nm}.

The NMOS-current-mirror disable transistor cfdisNM is electrically connected to the NMOS-current-mirror bias node ND_{mrr_nm}, and the NMOS-current-mirror disable transistor cfdisNM receives the negative pull-up switching-signal SWB_P from the switching-signal generation circuit swGenCKT. The NMOS-current-mirror disable transistor cfdisNM is selectively turned on according to the logic-level of the negative pull-up switching-signal SWB_P. When the NMOS-current-mirror disable transistor cfdisNM is turned on, the voltage of the NMOS-current-mirror bias node ND_{mrr_nm} is equivalent to the ground voltage Gnd (ND_{mrr_nm}=Gnd), and the positive NMOS-current-mirror transistor nmrr_pNM and the negative NMOS-current-mirror transistor nmrr_nNM are turned off. Conversely, when the NMOS-current-mirror disable transistor cfdisNM is turned off, the NMOS-current-mirror disable transistor cfdisNM does not affect the ON/OFF states of the positive NMOS-current-mirror transistor nmrr_pNM and the negative NMOS-current-mirror transistor nmrr_nNM.

Based on the architecture of the PMOS current-mirror pMRR, when the positive PMOS-current-mirror transistor pmrr_pPM and the negative PMOS-current-mirror transistor pmrr_nPM are turned on, the comparator reference current I_{pPM} flowing through the positive PMOS-current-mirror transistor pmrr_pPM is equivalent to the comparator mirror current I_{nPM} flowing through the negative PMOS-current-mirror transistor pmrr_nPM (I_{pPM}=I_{nPM}). The comparator reference current I_{pPM} flowing through the positive PMOS-current-mirror transistor pmrr_pPM and the comparator mirror current I_{nPM} flowing through the negative PMOS-current-mirror transistor pmrr_nPM are combined into a bias mirror current I_{nNM} (I_{pPM}+I_{nPM}=I_{nNM}), which then flows through the negative NMOS-current-mirror transistor nmrr_nNM. In addition, based on the architecture of the NMOS current-mirror nMRR, when both the positive NMOS-current-mirror transistor nmrr_pNM and the negative NMOS-current-mirror transistor nmrr_nNM are turned on, the bias reference current I_{pNM} flowing through the positive NMOS-current-mirror transistor nmrr_pNM is equivalent to the bias mirror current I_{nNM} flowing through the negative NMOS-current-mirror transistor nmrr_nNM (I_{pNM}=I_{nNM}).

Please refer to FIG. 6, which is a schematic diagram illustrating internal components and related signals of the driving circuit DRV according to the present disclosure. The driving circuit DRV includes a pull-up circuit upCKT, a pull-down circuit dnCKT, a driving enable transmission-gate enTG, and an output impedance Rout. One end of each of the pull-up circuit upCKT, the pull-down circuit dnCKT, and the driving enable transmission-gate enTG is electrically connected to a capacitor feedback node ND_{Cfb}. The other end of the driving enable transmission-gate enTG is electrically connected to the output impedance Rout.

The driving enable transmission-gate enTG receives the driving enable-signal EN from the external controller extCTL. The driving enable transmission-gate enTG is selectively turned on according to the driving enable-signal EN. When the driving enable-signal EN is at a high logic-level H (EN=H), the driving enable transmission-gate enTG is turned on, and the driver output signal outSIG is determined by one of the pull-up circuit upCKT and the pull-down circuit dnCKT. When the driving enable-signal EN is at a low logic-level L (EN=L), the driving enable transmission-gate enTG is turned off, and the driver output signal outSIG is floating.

The pull-up circuit upCKT includes a pull-up transistor upPM, a pull-up transmission-gate upTG, and a pull-up capacitor Cup. In the pull-up transistor upPM, the source terminal is electrically connected to the supply voltage node Vcc, the gate terminal is electrically connected to the pull-up transistor-gating node ND_{PG18}, and the drain terminal is electrically connected to the capacitor feedback node ND_{Cfb}. The pull-up transmission-gate upTG is electrically connected between the pull-up transistor-gating node ND_{PG18} and the pull-up capacitor node ND_{Cup}. The pull-up capacitor Cup is electrically connected between the pull-up capacitor node ND_{Cup} and the capacitor feedback node ND_{Cfb}. The pull-up circuit upCKT receives the positive pull-up switching-signal SW_P from the switching-signal generation circuit swGenCKT. The pull-up transmission-gate upTG, the pull-up disable transistor updisPM, and the pull-up bypass transistor upbpPM are selectively turned on according to the positive pull-up switching-signal SW_P.

The pull-down circuit dnCKT includes a pull-down transistor dnNM, a pull-down transmission-gate dnTG, and a pull-down capacitor Cdn. In the pull-down transistor dnNM, the source terminal is electrically connected to the ground voltage node Gnd, the gate terminal is electrically connected to the pull-down transistor-gating node ND_{NG18}, and the drain terminal is electrically connected to the capacitor feedback node ND_{Cfb}. The pull-down transmission-gate dnTG is electrically connected between the pull-down transistor-gating node ND_{NG18} and the pull-down capacitor node ND_{Cdn}. The pull-down capacitor Cdn is electrically connected between the pull-down capacitor node ND_{Cdn} and the capacitor feedback node ND_{Cfb}. The pull-down circuit dnCKT receives the positive pull-down switching-signal SW_N from the switching-signal generation circuit swGenCKT. The pull-down transmission-gate dnTG is selectively turned on according to the positive pull-down switching-signal SW_N, and the pull-down disable transistor dndisNM and the pull-down bypass transistor dpbpNM are selectively turned on according to the negative pull-down switching-signal SWB_N.

According to concepts of the present disclosure, the capacitance value of the pull-up capacitor Cup is greater than the capacitance value of the pull-down capacitor Cdn. For example, the capacitance value of the pull-up capacitor Cup is 330 fF, and the capacitance value of the pull-down capacitor Cdn is 80 fF. The capacitance values herein are provided for illustrative purposes only and are not limited in actual applications.

Please refer to FIG. 7, which is a schematic diagram illustrating internal components and related signals of the compensation circuit compCKT according to the present disclosure. The compensation circuit compCKT includes a compensation reference current-path comp_refPATH, K compensation current-paths comp_curPATH[1]~comp_curPATH[K], and K additional current-paths add_curPATH[1]~add_curPATH[K], where the variable K is a positive integer.

The compensation reference current-path comp_refPATH is electrically connected to the supply voltage node Vcc, the compensation bias node ND_{mrr_comp}, and the ground voltage node Gnd. The compensation current-paths comp_curPATH[1]~comp_curPATH[K] are electrically connected to the driver output node NDₒᵤₜ, the compensation bias node ND_{mrr_comp}, and the ground voltage node Gnd. The additional current-paths add_curPATH[1]~add_curPATH[K] are electrically connected to the driver output node NDₒᵤₜ, the additional current-path enable circuit addEnCKT, and the ground voltage node Gnd.

The compensation disable transistor comp_disNM selectively pulls down the voltage of the compensation bias node ND_{mrr_comp} to the ground voltage Gnd according to the logic-level of the negative pull-up switching-signal SWB_P. In addition, the compensation reference current-path comp_refPATH, the compensation current-paths comp_curPATH[1]~comp_curPATH[K] and the additional current-paths add_curPATH[1]~add_curPATH[K] are disabled or respectively generate a compensation reference current I_{comp_ref}, K compensation currents I_{comp_iq}, and K additional currents I_{add_iq} according to the voltage of the compensation bias node ND_{mrr_comp}. The K compensation currents I_{comp_iq} and the K additional currents I_{add_iq} are quiescent currents used to pull down the driver output signal outSIG. In an embodiment, the additional current-paths add_curPATH[1]~add_curPATH[K] are optional.

When the compensation disable transistor comp_disNM is turned on, the compensation disable transistor comp_disNM pulls down the voltage of the compensation bias node ND_{mrr_comp} to the ground voltage Gnd. Thus, the compensation reference current-path comp_refPATH stops generating the compensation reference current I_{comp_ref}, the compensation current-paths comp_curPATH[1]~comp_curPATH[K] stop generating the compensation current I_{comp_iq}, and the additional current-paths add_curPATH[1]~add_curPATH[K] stop generating the additional current I_{add_iq}.

Conversely, when the compensation disable transistor comp_disNM is turned off, whether the compensation reference current-path comp_refPATH generates the compensation reference current I_{comp_ref} or not depends on the voltage of the non-inverting output-terminal cfout+ of the comparison circuit cfCKT (equivalent to the compensation enable node ND_{comp_en}); whether the compensation current-path comp_curPATH generates the compensation current I_{comp_iq} or not depends on the logic-level of the positive pull-up switching-signal SW_P; and whether the additional current-path add_curPATH generates the additional current I_{add_iq} or not depends on the logic-level of the additional current-path enable-signal IQ_EN.

The additional current-path enable-signal IQ_EN is output by the additional current-path enable circuit addEnCKT. Therefore, the additional current-path enable-signal IQ_EN depends on the input signal of the additional current-path enable circuit addEnCKT, that is, the logic-level of the positive pull-up switching-signal SW_P and the logic-level of the external enable-signal IQ_extEN for the additional current-path(s). The following description gives a simplified case that the additional current-path enable-signal IQ_EN is at a low logic-level (IQ_EN=L), thereby disabling the additional current-paths add_curPATH[1]~add_curPATH[K].

According to concepts of the present disclosure, the additional current-path enable circuit addEnCKT could be an AND gate. Suppose the external controller extCTL will not enable the additional current-paths add_curPATH[1]~add_curPATH[K]. In that case, the external controller extCTL sets the external enable-signal IQ_extEN for the additional current-path(s) to a low logic-level L (IQ_extEN=L) to disable the additional current-paths add_curPATH[1]~add_curPATH[K]. At this time, no matter how the positive pull-up switching-signal SW_P changes, the additional current-path enable-signal IQ_EN output by the additional current-path enable circuit addEnCKT remains at the low logic-level L (IQ_EN=L). That is, IQ_EN=L if IQ_extEN=L. Conversely, if the external controller extCTL wants to enable the additional current-paths add_curPATH[1]~add_curPATH[K], the external controller extCTL sets the external enable-signal IQ_extEN for the additional current-path(s) to maintain a high logic-level H (IQ_extEN=H). At this time, the additional current-path enable-signal IQ_EN output by the additional current-path enable circuit addEnCKT changes with the positive pull-up switching-signal SW_P. That is, IQ_EN=SW_P if IQ_extEN=H.

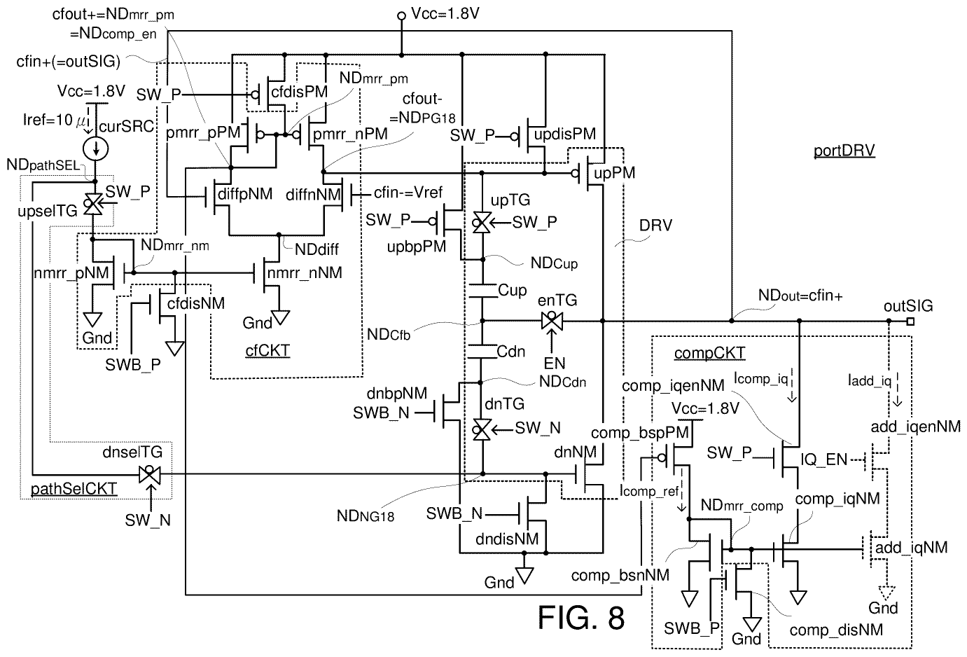

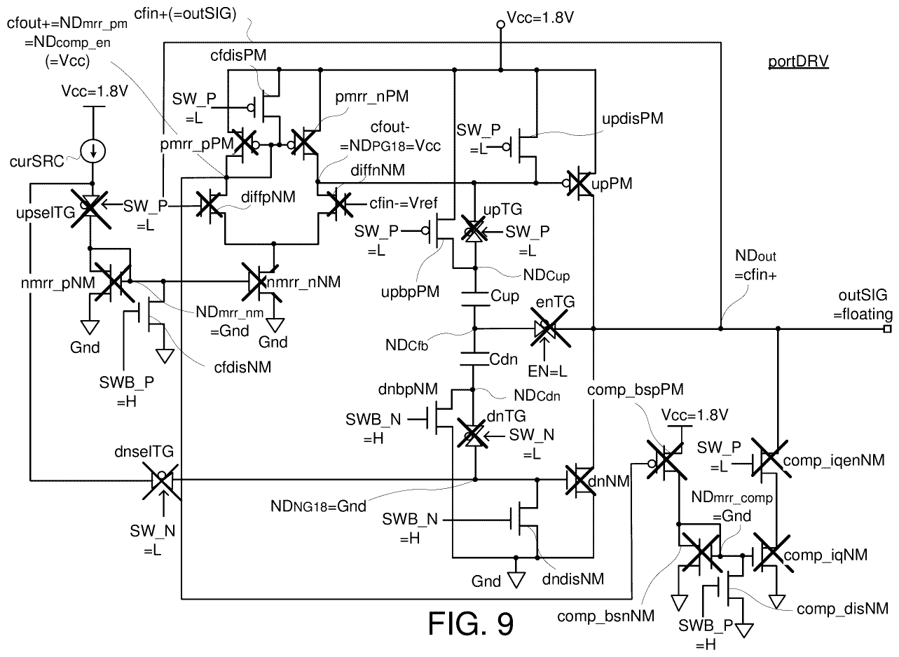

The above description, with reference to the accompanying drawings, has provided the details of the respective components. For example, FIG. 3 illustrates the logic circuits for constructing the switching-signal generation circuit swGenCKT; FIG. 4 illustrates the internal components and related signals of the port control module portCtrlMDL; FIG. 5 illustrates the internal components and related signals of the comparison circuit cfCKT; FIG. 6 illustrates the internal components and related signals of the driving circuit DRV; and FIG. 7 illustrates the internal components and related signals of the compensation circuit compCKT. Next, the present disclosure will summarize the circuit components of FIGS. 4~7 in FIG. 8. Based on the circuit diagram shown in FIG. 8, FIGS. 9-14 further illustrate the circuit behavior of the driver portDRV in response to different logic-levels of the driving enable-signal EN and the driver input signal inDAT.

Please refer to FIG. 8, which is a circuit diagram of the driver portDRV according to the present disclosure. In FIGS. 3, 5, and 6, the circuit components of the switching-signal generation circuit swGenCKT, the comparison circuit cfCKT, and the driving circuit DRV have been described in detail, respectively. It will be further described how to use transistors to implement the port control module portCtrlMDL in FIG. 4 and the compensation circuit compCKT in FIG. 7.

First, it is explained how to implement the port control module portCtrlMDL with transistors. As shown in FIG. 4, the port control module portCtrlMDL includes the reference current source curSRC, the path-selection circuit pathSelCKT, the PMOS-current-mirror disable transistor cfdisPM, the NMOS-current-mirror disable transistor cfdisNM, the pull-up disable transistor updisPM, the pull-up bypass transistor upbpPM, the pull-down disable transistor dndisNM, the pull-down bypass transistor dnbpNM, and the compensation disable transistor comp_disNM. These components and connections are described below. Please refer to FIGS. 4 and 8 together.

The reference current source curSRC is electrically connected between the supply voltage node Vcc and the path-selection node ND_{pathSEL}. The reference current source curSRC is used to provide a reference current Iref (10 μA, for example).

The path-selection circuit pathSelCKT includes a pull-up path-selection transmission-gate upselTG and a pull-down path-selection transmission-gate dnselTG. The pull-up path-selection transmission-gate upselTG is controlled by the positive pull-up switching-signal SW_P, and the pull-down path-selection transmission-gate dnselTG is controlled by the positive pull-down switching-signal SW_N.

The pull-up path-selection transmission-gate upselTG is electrically connected between the path-selection node ND_{pathSEL} and the NMOS-current-mirror bias node ND_{mrr_nm}. When the positive pull-up switching-signal SW_P is at a high logic-level H (SW_P=H), the pull-up path-selection transmission-gate upselTG is turned on. Conversely, when the positive pull-up switching-signal SW_P is at a low logic-level L (SW_P=L), the pull-up path-selection transmission-gate upselTG is turned off.

The pull-down path-selection transmission-gate dnselTG is electrically connected between the path-selection node ND_{pathSEL} and the pull-down transistor-gating node ND_{NG18}. When the positive pull-down switching-signal SW_N is at a high logic-level H (SW_N=H), the pull-down path-selection transmission-gate dnselTG is turned on. Conversely, when the positive pull-down switching-signal SW_N is at a low logic-level L (SW_N=L), the pull-down path-selection transmission-gate dnselTG is turned off.

Because the positive pull-up switching-signal SW_P and the positive pull-down switching-signal SW_N have opposite phases when the driving enable-signal EN is at a high logic-level H (EN=H), the pull-up path-selection transmission-gate upselTG and the pull-down path-selection transmission-gate dnselTG will be turned on alternately.

When the pull-up path-selection transmission-gate upselTG is turned on and the pull-down path-selection transmission-gate dnselTG is turned off, the reference current Iref flows through the pull-up path-selection transmission-gate upselTG, and the pull-up path-selection transmission-gate upselTG conducts the supply voltage Vcc to the NMOS-current-mirror bias node ND_{mrr_nm}. When the pull-up path-selection transmission-gate upselTG is turned off and the pull-down path-selection transmission-gate dnselTG is turned on, the reference current Iref flows through the pull-down path-selection transmission-gate dnselTG, and the pull-down path-selection transmission-gate dnselTG conducts the supply voltage Vcc to the pull-down transistor-gating node ND_{NG18}.

Next, the connections of the transistors in the port control module portCtrlMDL are explained. As shown in FIG. 8, the pull-up disable transistor updisPM and the pull-up bypass transistor upbpPM are PMOS transistors, and the pull-down disable transistor dndisNM and the pull-down bypass transistor dnbpNM are NMOS transistors. The pull-up disable transistor updisPM and the pull-up bypass transistor upbpPM are related to the operation of the pull-up circuit upCKT, and the pull-down disable transistor dndisNM and the pull-down bypass transistor dnbpNM are related to the operation of the pull-down circuit dnCKT. The connections and related operation methods of these circuit components are fully explained below.

In the pull-up disable transistor updisPM, the source terminal is electrically connected to the supply voltage node Vcc, the gate terminal receives the positive pull-up switching-signal SW_P, and the drain terminal is electrically connected to the inverting output-terminal cfout− of the comparison circuit cfCKT. Therefore, whether the pull-up disable transistor updisPM is turned on or off depends on the logic-level of the positive pull-up switching-signal SW_P. When the positive pull-up switching-signal SW_P is at a high logic-level H (SW_P=H), the pull-up disable transistor updisPM is turned off without affecting the voltage of the inverting output-terminal cfout− of the comparison circuit cfCKT (equivalent to the voltage of the pull-up transistor-gating node ND_{PG18}). Conversely, when the positive pull-up switching-signal SW_P is at a low logic-level L (SW_P=L), the pull-up disable transistor updisPM is turned on and the voltage of the inverting output-terminal cfout− of the comparison circuit cfCKT (equivalent to the voltage of the pull-up transistor-gating node ND_{PG18}) is set to the supply voltage Vcc. That is, cfout−=ND_{PG18}=Vcc.

In the pull-up bypass transistor upbpPM, the source terminal is electrically connected to the supply voltage node Vcc, the gate terminal receives the positive pull-up switching-signal SW_P, and the drain terminal is electrically connected to the pull-up capacitor node ND_{Cup}. Therefore, whether the pull-up bypass transistor upbpPM is turned on or off depends on the logic-level of the positive pull-up switching-signal SW_P. When the positive pull-up switching-signal SW_P is at a high logic-level H (SW_P=H), the pull-up bypass transistor upbpPM is turned off without affecting the voltage of the pull-up capacitor node ND_{Cup}. Conversely, when the positive pull-up switching-signal SW_P is at a low logic-level L (SW_P=L), the pull-up bypass transistor upbpPM is turned on and the voltage of the pull-up capacitor node ND_{Cup} is set to the supply voltage Vcc. That is, ND_{Cup}=Vcc.

In the pull-down disable transistor dndisNM, the drain terminal is electrically connected to the pull-down transistor-gating node ND_{NG18}, the gate terminal receives the negative pull-down switching-signal SWB_N, and the source terminal is electrically connected to the ground voltage node Gnd. Therefore, whether the pull-down disable transistor dndisNM is turned on or not depends on the logic-level of the negative pull-down switching-signal SWB_N. When the negative pull-down switching-signal SWB_N is at a low logic-level L (SWB_N=L), the pull-down disable transistor dndisNM is turned off without affecting the voltage of the pull-down transistor-gating node ND_{NG18}. Conversely, when the negative pull-down switching-signal SWB_N is at a high logic-level H (SWB_N=H), the pull-down disable transistor dndisNM is turned on and the pull-down transistor-gating node ND_{NG18} is set to the ground voltage Gnd. That is, ND_{NG18}=Gnd.

In the pull-down bypass transistor dnbpNM, the drain terminal is electrically connected to the pull-down capacitor node ND_{Cdn}, the gate terminal receives the negative pull-down switching-signal SWB_N, and the source terminal is electrically connected to the ground voltage node Gnd. Therefore, whether the pull-down bypass transistor dnbpNM is turned on or off depends on the logic-level of the negative pull-down switching-signal SWB_N. When the negative pull-down switching-signal SWB_N is at a low logic-level L (SWB_N=L), the pull-down bypass transistor dnbpNM is turned off without affecting the voltage of the pull-down capacitor node ND_{Cdn}. Conversely, when the negative pull-down switching-signal SWB_N is at a high logic-level H (SWB_N=H), the pull-down bypass transistor dnbpNM is turned on and the voltage of the pull-down capacitor node ND_{Cdn} is set to the ground voltage Gnd. That is, ND_{Cdn}=Gnd.

Next, the connections of the pull-up disable transistor updisPM, the pull-up bypass transistor upbpPM, the pull-up transmission-gate upTG, and the pull-up transistor upPM are further described. It is obtained from FIG. 8 that whether the pull-up disable transistor updisPM, the pull-up bypass transistor upbpPM, and the pull-up transmission-gate upTG are turned on or off depends on the logic-level of the positive pull-up switching-signal SW_P.

Accordingly, when the positive pull-up switching-signal SW_P is at a low logic-level L (SW_P=L), the pull-up disable transistor updisPM and the pull-up bypass transistor upbpPM are turned on, and the pull-up transmission-gate upTG is turned off. At this time, the voltage of the inverting output-terminal cfout− of the comparison circuit cfCKT (equivalent to the voltage of the pull-up transistor-gating node ND_{PG18}) is set to the supply voltage Vcc, thereby turning off the pull-up transistor upPM. Conversely, when the positive pull-up switching-signal SW_P is at a high logic-level H (SW_P=H), the pull-up disable transistor updisPM and the pull-up bypass transistor upbpPM are turned off, and the pull-up transmission-gate upTG is turned on. At this time, the voltage of the inverting output-terminal cfout− of the comparison circuit cfCKT (equivalent to the voltage of the pull-up transistor-gating node ND_{PG18}) depends on the driver output signal outSIG and the reference voltage Vref received by the comparison circuit cfCKT.

Next, the connections of the pull-down disable transistor dndisNM, the pull-down bypass transistor dnbpNM, the pull-down transmission-gate dnTG, and the pull-down transistor dnNM are further described. It is obtained from FIG. 8 that whether the pull-down disable transistor dndisNM and the pull-down bypass transistor dnbpNM are turned on or off depends on the logic-level of the negative pull-down switching-signal SWB_N. On the other hand, whether the pull-down transmission-gate dnTG is turned on or off depends on the logic-level of the positive pull-down switching-signal SW_N.

The logic-levels of the negative pull-down switching-signal SWB_N and the logic-level of the positive pull-down switching-signal SW_N have opposite phases. When the pull-down disable transistor dndisNM and the pull-down bypass transistor dnbpNM are turned on due to the high logic-level H of the negative pull-down switching-signal SWB_N (SWB_N=H), the pull-down transmission-gate dnTG is turned off due to the low logic-level L of the positive pull-down switching-signal SW_N (SW_N=L). At this time, the voltage of the pull-down transistor-gating node ND_{NG18} is equivalent to the ground voltage Gnd because the pull-down disable transistor dndisNM is turned on, thereby turning off the pull-down transistor dnNM.

Conversely, when the pull-down disable transistor dndisNM and the pull-down bypass transistor dnbpNM are turned off due to the low logic-level L of the negative pull-down switching-signal SWB_N (SWB_N=L), the pull-down transmission-gate dnTG is turned on due to the high logic-level H of the positive pull-down switching-signal SW_N (SW_N=H). At this time, whether the pull-down transistor dnNM is turned on depends on the voltage of the pull-down transistor-gating node ND_{NG18}. In addition, since the pull-down path-selection transmission-gate dnselTG is turned on due to the high logic-level H of the positive pull-down switching-signal SW_N (SW_N=H), the voltage of the pull-down transistor-gating node ND_{NG18} at this time is equivalent to the voltage of the path-selection node ND_{pathSEL} (equivalent to the supply voltage Vcc). That is, ND_{NG18}=ND_{pathSEL}=Vcc. It is derived that the pull-down transistor dnNM in this case is turned on.

According to the above description, it is obtained that when the driving enable-signal EN is at a high logic-level H (EN=H), the ON/OFF state of the pull-up disable transistor updisPM is consistent with that of the pull-up bypass transistor upbpPM, and is opposite to that of the pull-up transmission-gate upTG. It is also obtained that the ON/OFF state of the pull-down disable transistor dndisNM is consistent with that of the pull-down bypass transistor dnbpNM, and is opposite to that of the pull-down transmission-gate dnTG.

The compensation disable transistor comp_disNM is an NMOS transistor. In the compensation disable transistor comp_disNM, the drain terminal is electrically connected to the compensation bias node ND_{mrr_comp}, the gate terminal receives the negative pull-up switching-signal SWB_P, and the source terminal is electrically connected to the ground voltage node Gnd.

Accordingly, when the negative pull-up switching-signal SWB_P is at a high logic-level H (SWB_P=H), the compensation disable transistor comp_disNM is turned on to make the voltage of the compensation bias node ND_{mrr_comp} equivalent to the ground voltage Gnd. Once the voltage of the compensation bias node ND_{mrr_comp} is equivalent to the ground voltage Gnd, the compensation reference current-path comp_refPATH, the compensation current-path comp_curPATH, and the additional current-path add_curPATH are all disabled, and no current flows therethrough. Conversely, when the negative pull-up switching-signal SWB_P is at a low logic-level L (SWB_P=L), the compensation disable transistor comp_disNM is turned off. At this time, the compensation disable transistor comp_disNM does not affect the operation of the compensation reference current-path comp_refPATH, the compensation current-path comp_curPATH, and the additional current-path add_curPATH.

Next, the transistor implementation of the compensation circuit compCKT is described. Please refer to both FIGS. 7 and 8. The following description gives a simplified case of K=1 in the compensation circuit compCKT in FIG. 8. That is, the compensation circuit compCKT includes a compensation reference current-path comp_refPATH, one compensation current-path comp_curPATH, and one additional current-path add_curPATH.

The compensation reference current-path comp_refPATH includes a compensation pull-up bias transistor comp_bspPM and a compensation pull-down bias transistor comp_bsnNM. The compensation pull-up bias transistor comp_bspPM for the compensation reference current I_{comp_ref} is a PMOS transistor, and the compensation pull-down bias transistor comp_bsnNM is an NMOS transistor. In the compensation pull-up bias transistor comp_bspPM for the compensation reference current I_{comp_ref}, the source terminal is electrically connected to the supply voltage node Vcc, the gate terminal is electrically connected to the PMOS-current-mirror bias node ND_{mrr_pm}, and the drain terminal is electrically connected to the compensation bias node ND_{mrr_comp}. On the other hand, in the compensation pull-down bias transistor comp_bsnNM for the compensation reference current I_{comp_ref}, both the drain terminal and the gate terminal are electrically connected to the compensation bias node ND_{mrr_comp}, and the source terminal is electrically connected to the ground voltage node Gnd. Therefore, when the compensation disable transistor comp_disNM is turned off, whether the compensation reference current I_{comp_ref} flows through the compensation reference current-path comp_refPATH or not depends on the voltage of the non-inverting output-terminal cfout+ of the comparison circuit cfCKT.

The compensation current-path comp_curPATH includes a compensation current-path enable transistor comp_iqenNM and a compensation current-path transistor comp_iqNM. Both the compensation current-path enable transistor comp_iqenNM and the compensation current-path transistor comp_iqNM are NMOS transistors. In the compensation current-path enable transistor comp_iqenNM, the drain terminal is electrically connected to the driver output node NDₒᵤₜ, the gate terminal receives the positive pull-up switching-signal SW_P, and the source terminal is electrically connected to the drain terminal of the compensation current-path transistor comp_iqNM. Further, in the compensation current-path transistor comp_iqNM, the gate terminal is electrically connected to the compensation bias node ND_{mrr_comp}, and the source terminal is electrically connected to the ground voltage node Gnd. Therefore, when the compensation disable transistor comp_disNM is turned off, whether the compensation current I_{comp_iq} flows through the compensation current-path comp_curPATH depends on the logic-level of the positive pull-up switching-signal SW_P.

The additional current-path add_curPATH includes an additional current-path enable transistor add_iqenNM and an additional current-path transistor add_iqNM. Both the additional current-path enable transistor add_iqenNM and the additional current-path transistor add_iqNM are NMOS transistors.

In the additional current-path enable transistor add_iqenNM, the drain terminal is electrically connected to the driver output node NDₒᵤₜ, the gate terminal receives the additional current-path enable-signal IQ_EN, and the source terminal is electrically connected to the drain terminal of the additional current-path transistor add_iqNM. Further, in the additional current-path transistor add_iqNM, the gate terminal is electrically connected to the compensation bias node ND_{mrr_comp}, and the source terminal is electrically connected to the ground voltage node Gnd. Therefore, when the compensation disable transistor comp_disNM is turned off, whether the additional current I_{add_iq} flows through the additional current-path add_curPATH depends on the logic-level of the additional current-path enable-signal IQ_EN.

Table 2 shows the current-paths included in the compensation circuit compCKT, the transistors included in each current-path, and the currents flowing through the corresponding current-paths.

TABLE 2

| | | current flowing |
|---|---|---|
| | transistors included | through the |
| current-path | in the current-path | current-path |
| compensation | compensation pull-up bias | compensation |
| reference | transistor comp_bspPM, | reference |
| current-path | compensation pull-down bias | current |
| comp_refPATH | transistor comp_bsnNM | I_{comp}_{_{—}}_{ref} |
| compensation | compensation current-path | compensation |
| current-path | enable transistor | current I_{comp}_{_{—}}_{iq} |
| comp_curPATH | comp_iqenNM, | |
| | compensation current-path | |
| | transistor comp_iqNM | |
| additional | additional current-path enable | additional |
| current-path | transistor add_iqenNM, | current |
| add_curPATH | additional current-path | I_{add}_{_{—}}_{iq}. |
| | transistor add_iqNM | |

Please refer to FIG. 9, which is a schematic diagram showing circuit behavior of the driver portDRV according to the present disclosure when the driving enable-signal EN is at a low logic-level L (EN=L). As shown in Table 1, when the driving enable-signal EN is at a low logic-level L (EN=L), both the positive pull-up switching-signal SW_P and the positive pull-down switching-signal SW_N remain at a low logic-level L (SW_P=SW_N=L); and both the negative pull-up switching-signal SWB_P and the negative pull-down switching-signal SWB_N remain at a high logic-level H (SWB_P=SWB_N=H). The circuit behavior related to the pull-up path, the pull-down path, and the compensation circuit compCKT in FIG. 9 will be sequentially described.

In the pull-up path, because the positive pull-up switching-signal SW_P is at a low logic-level L (SW_P=L), the pull-up path-selection transmission-gate upselTG is turned off, the PMOS-current-mirror disable transistor cfdisPM is turned on, the pull-up disable transistor updisPM is turned on, the pull-up bypass transistor upbpPM is turned on, and the pull-up transmission-gate upTG is turned off. And, because the negative pull-up switching-signal SWB_P is at a high logic-level H (SWB_P=H), the NMOS-current-mirror disable transistor cfdisNM is turned on.

In the comparison circuit cfCKT, because the NMOS-current-mirror disable transistor cfdisNM is turned on, the NMOS-current-mirror disable transistor cfdisNM conducts the ground voltage Gnd to the NMOS-current-mirror bias node ND_{mrr_nm}. That is, ND_{mrr_nm}=Gnd. As a result, the positive NMOS-current-mirror transistor nmrr_pNM and the negative NMOS-current-mirror transistor nmrr_nNM are turned off.

In addition, because the PMOS-current-mirror disable transistor cfdisPM is turned on, the PMOS-current-mirror disable transistor cfdisPM transmits the supply voltage Vcc to the PMOS-current-mirror bias node ND_{mrr_pm}. That is, ND_{mrr_pm}=cfout+=Vcc. As a result, the positive PMOS-current-mirror transistor pmrr_pPM and the negative PMOS-current-mirror transistor pmrr_nPM are turned off.

In the pull-up circuit upCKT, the gate terminal of the pull-up transistor upPM is controlled by the voltage of the pull-up transistor-gating node ND_{PG18}. Because the pull-up disable transistor updisPM is turned on, the voltage of the pull-up transistor-gating node ND_{PG18} is equivalent to the supply voltage Vcc. That is, ND_{PG18}=Vcc. Therefore, the pull-up transistor upPM is turned off. Accordingly, in FIG. 9, the pull-up transistor upPM does not affect the driver output signal outSIG.

In the pull-down path, because the positive pull-down switching-signal SW_N is at a low logic-level L (SW_N=L), the pull-down path-selection transmission-gate dnselTG and the pull-down transmission-gate dnTG are turned off. Also, because the negative pull-down switching-signal SWB_N is at a high logic-level H (SWB_N=H), the pull-down bypass transistor dnbpNM and the pull-down disable transistor dndisNM are turned on.

As the pull-down disable transistor dndisNM is turned on, the pull-down disable transistor dndisNM conducts the ground voltage Gnd to the pull-down transistor-gating node ND_{NG18}, so the voltage of the pull-down transistor-gating node ND_{NG18} is equivalent to the ground voltage Gnd. That is, ND_{NG18}=Gnd. Thus, the pull-down transistor dnNM is turned off because the pull-down transistor-gating node ND_{NG18} is equivalent to the ground voltage Gnd. Therefore, in FIG. 9, the pull-down transistor dnNM does not affect the driver output signal outSIG.

In the compensation circuit compCKT, because the positive pull-up switching-signal SW_P is at a low logic-level L (SW_P=L), the compensation current-path enable transistor comp_iqenNM is turned off. And, because the negative pull-up switching-signal SWB_P is at a high logic-level H (SWB_P=H), the compensation disable transistor comp_disNM is turned on. The compensation disable transistor comp_disNM in the ON state conducts the ground voltage Gnd to the compensation bias node ND_{mrr_comp}. That is, ND_{mrr_comp}=Gnd. Thus, the compensation pull-down bias transistor comp_bsnNM for the compensation reference current I_{comp_ref} and the compensation current-path transistor comp_iqNM are turned off. Therefore, in FIG. 9, the compensation circuit compCKT does not affect the driver output signal outSIG.

On the other hand, because the voltage of the non-inverting output-terminal cfout+ of the comparison circuit cfCKT, electrically connected to the gate terminal of the compensation pull-up bias transistor comp_bspPM for the compensation reference current I_{comp_ref}, is equivalent to the supply voltage Vcc, the compensation pull-up bias transistor comp_bspPM for the compensation reference current I_{comp_ref} is also turned off.

In FIG. 9, the driving enable transmission-gate enTG is turned off because the driving enable-signal EN is at a low logic-level (EN=L). Accordingly, in FIG. 9, the driver output signal outSIG is floating. Thus, the positive differential-input transistor diffpNM and the negative differential-input transistor diffnNM are also turned off.

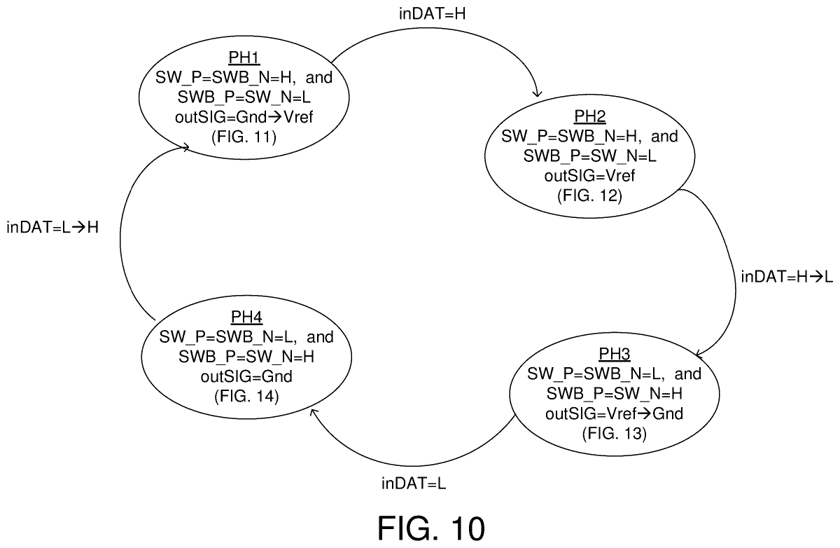

As described above, when the driving enable-signal EN is at a low logic-level L (EN=L), the driver output signal outSIG is floating. In the subsequent description with reference to FIGS. 10-21 explain the circuit behavior of the driver portDRV in response to the change of the driver input signal inDAT. It is supposed in the description that the driving enable-signal EN is at a high logic-level H (EN=H).

Please refer to FIG. 10, which is a schematic state diagram showing how the port control module portCtrlMDL of the present disclosure controls the circuit behavior of the driver portDRV in response to the change of the driver input signal inDAT when the driving enable-signal EN is at a high logic-level H (EN=H). The driver portDRV may operate in a rising-transition phase PH1, a high-level stable phase PH2, a falling-transition phase PH3, and a low-level stable phase PH4 in response to the driver input signal inDAT. The following description relates to the circuit behavior of the driver portDRV in response to the change of the driver input signal inDAT. The description explains the logic-levels of the positive pull-up switching-signal SW_P, the negative pull-up switching-signal SWB_P, the positive pull-down switching-signal SW_N, the negative pull-down switching-signal SWB_N, and the voltage of the driver output signal outSIG during the rising-transition phase PH1, the high-level stable phase PH2, the falling-transition phase PH3, and the low-level stable phase PH4, respectively.

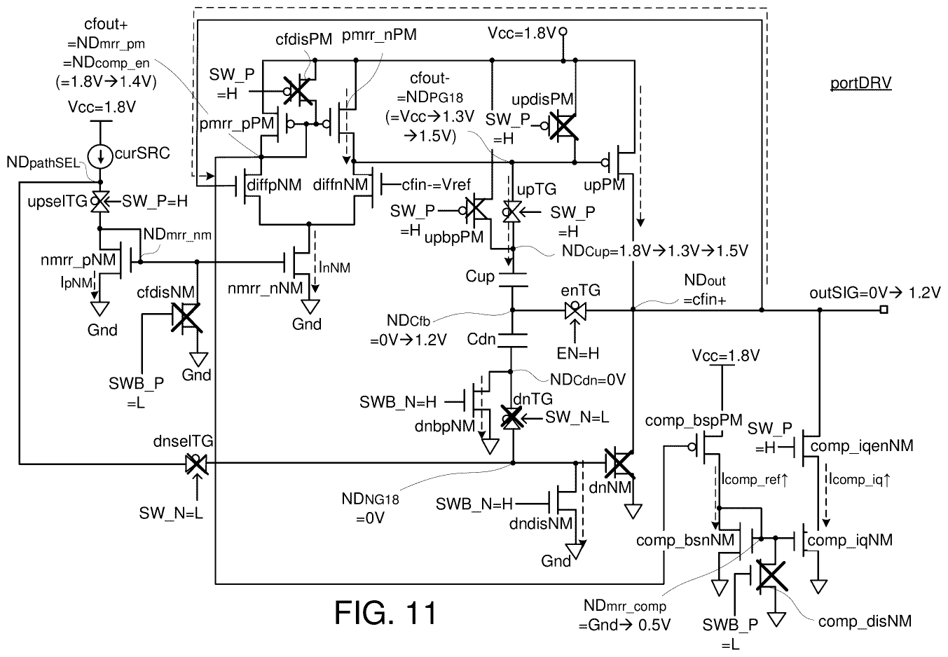

When the driver input signal inDAT is in a transient state changing from a low logic-level L to a high logic-level H, the driver portDRV is in the rising-transition phase PH1. At this time, the positive pull-up switching-signal SW_P and the negative pull-down switching-signal SWB_N are at a high logic-level H (SW_P=SWB_N=H); and the negative pull-up switching-signal SWB_P and the positive pull-down switching-signal SW_N are at a low logic-level L (SWB_P=SW_N=L). On the other hand, the voltage of the driver output signal outSIG gradually rises from the ground voltage Gnd to the reference voltage Vref (outSIG=Gnd→Vref). FIG. 11 shows the circuit behavior of the driver portDRV during the rising-transition phase PH1.

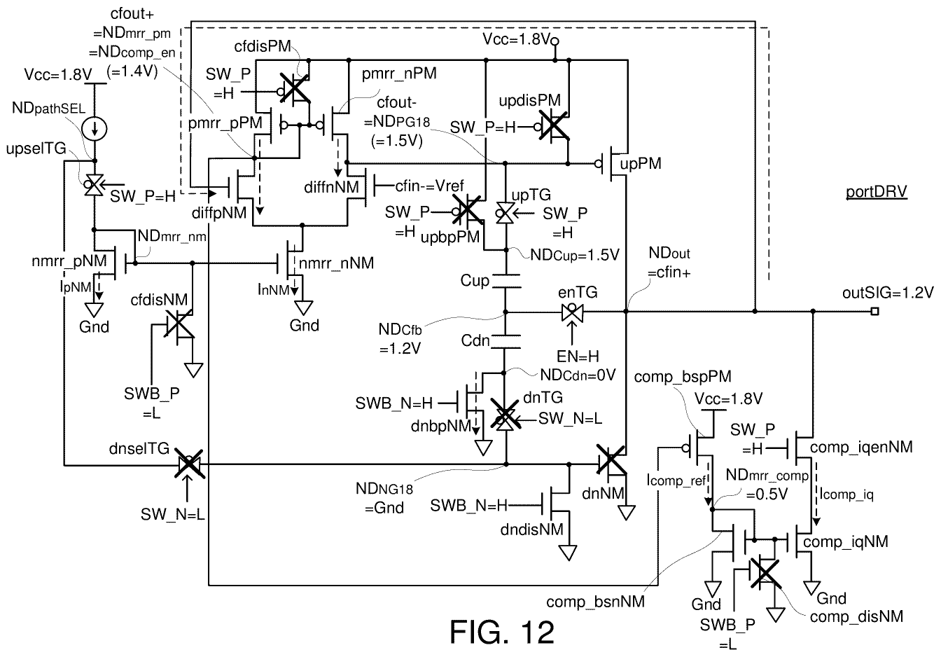

When the driver input signal inDAT is in a stable state having a high logic-level H, the driver portDRV is in the high-level stable phase PH2. At this time, the positive pull-up switching-signal SW_P and the negative pull-down switching-signal SWB_N are at a high logic-level H (SW_P=SWB_N=H); and the negative pull-up switching-signal SWB_P and the positive pull-down switching-signal SW_N are at a low logic-level L (SWB_P=SW_N=L). On the other hand, the driver output signal outSIG remains at the reference voltage Vref. That is, outSIG=Vref. FIG. 12 shows the circuit behavior of the driver portDRV during the high-level stable phase PH2.

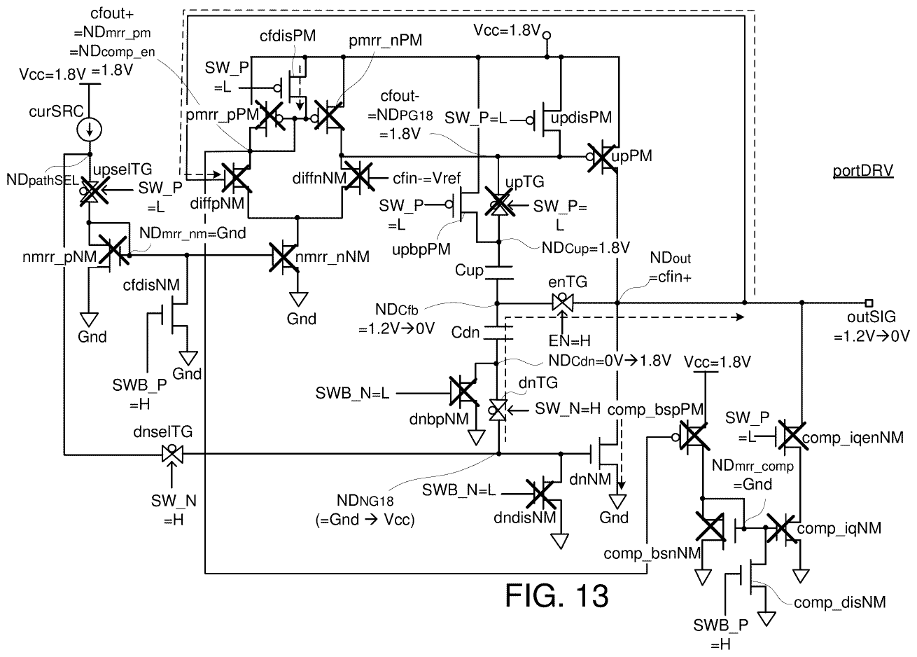

When the driver input signal inDAT is in a transient state changing from a high logic-level H to a low logic-level L, the driver portDRV is in the falling-transition phase PH3. At this time, the positive pull-up switching-signal SW_P and the negative pull-down switching-signal SWB_N are at low logic-level L (SW_P=SWB_N=L); and the negative pull-up switching-signal SWB_P and the positive pull-down switching-signal SW_N are at a high logic-level H (SWB_P=SW_N=H). On the other hand, the voltage of the driver output signal outSIG gradually falls from the reference voltage Vref to the ground voltage Gnd (outSIG=Vref→Gnd). FIG. 13 shows the circuit behavior of the driver portDRV during the falling-transition phase PH3.

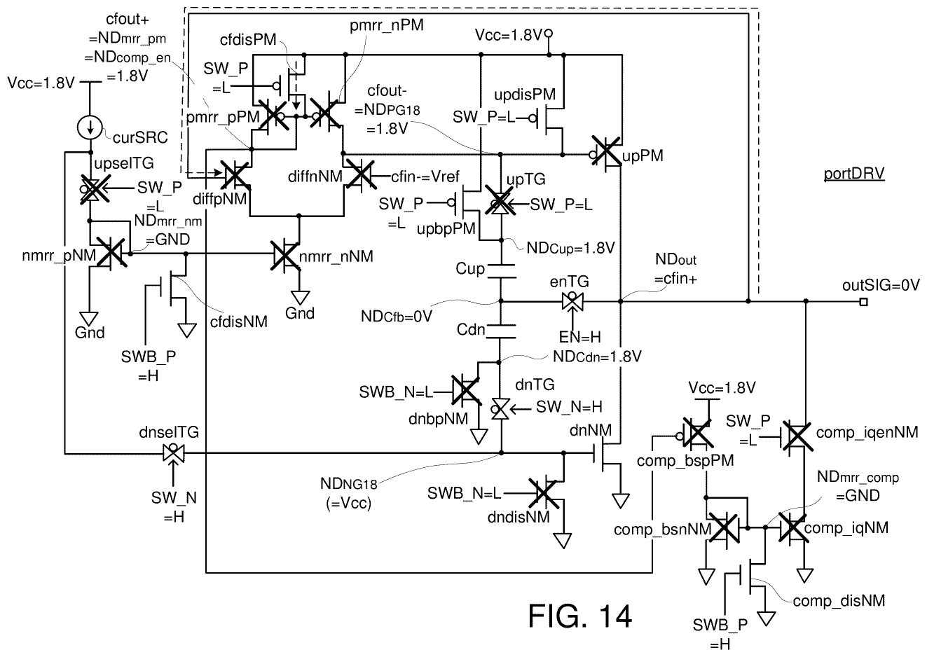

When the driver input signal inDAT is in the stable state having a low logic-level L, the driver portDRV is in the low-level stable phase PH4. At this time, the positive pull-up switching-signal SW_P and the negative pull-down switching-signal SWB_N are at a low logic-level L (SW_P=SWB_N=L); and the negative pull-up switching-signal SWB_P and the positive pull-down switching-signal SW_N are at a high logic-level H (SWB_P=SW_N=H). On the other hand, the driver output signal outSIG remains at the ground voltage Gnd. That is, outSIG=Gnd. FIG. 14 shows the circuit behavior of the driver portDRV during the low-level stable phase PH4.

According to the four phases listed in FIG. 10, the operation of the driving circuit DRV may be classified into two conditions. Please refer to both FIGS. 6 and 10.

In the first condition, the positive pull-up switching-signal SW_P is at a high logic-level H (SW_P=H); the positive pull-down switching-signal SW_N is at a low logic-level L (SW_N=L); and the negative pull-down switching-signal SWB_N is at a high logic-level H (SWB_N=H). In other words, the first condition corresponds to the rising-transition phase PH1 and the high-level stable phase PH2. The following description explains the behavior of the components of the pull-up circuit upCKT, and the pull-down circuit dnCKT, in the first condition.

In the pull-up circuit upCKT in the first condition, the pull-up transmission-gate upTG is turned on, and the pull-up disable transistor updisPM and the pull-up bypass transistor upbpPM are turned off. Therefore, the pull-up disable transistor updisPM does not affect the voltage of the pull-up transistor-gating node ND_{PG18}, and the pull-up bypass transistor upbpPM does not affect the voltage of the pull-up capacitor node ND_{Cup}. At this time, the pull-up transmission-gate upTG conducts the voltage of the pull-up transistor-gating node ND_{PG18} to the pull-up capacitor node ND_{Cup}. On the other hand, in the pull-down circuit dnCKT in the first condition, the pull-down transmission-gate dnTG is turned off, and the pull-down disable transistor dndisNM and the pull-down bypass transistor dnbpNM are turned on. The pull-down disable transistor dndisNM in the ON state conducts the ground voltage Gnd to the pull-down transistor-gating node ND_{NG18}, and the pull-down bypass transistor dnbpNM in the ON state conducts the ground voltage Gnd to the pull-down capacitor node ND_{Cdn}.

In the second condition, the positive pull-up switching-signal SW_P is at a low logic-level L (SW_P=L); the positive pull-down switching-signal SW_N is at a high logic-level H (SW_N=H); and the negative pull-down switching-signal SWB_N is at a low logic-level L (SWB_N=L). In other words, the second condition corresponds to the falling-transition phase PH3 and the low-level stable phase PH4. The following description explains the behavior of the components of the pull-up circuit upCKT, and the pull-down circuit dnCKT, in the second condition.

In the pull-up circuit upCKT in the second condition, the pull-up transmission-gate upTG is turned off, and the pull-up disable transistor updisPM and the pull-up bypass transistor upbpPM are turned on. At this time, the pull-up disable transistor updisPM in the ON state conducts the supply voltage Vcc to the pull-up transistor-gating node ND_{PG18}, and the pull-up bypass transistor upbpPM in the ON state conducts the supply voltage Vcc to the pull-up capacitor node ND_{Cup}. On the other hand, in the pull-down circuit dnCKT in the second condition, the pull-down transmission-gate dnTG is turned on, and the pull-down disable transistor dndisNM and the pull-down bypass transistor dnbpNM are turned off. At this time, the pull-down disable transistor dndisNM does not affect the voltage of the pull-down transistor-gating node ND_{NG18}, and the pull-down bypass transistor dnbpNM does not affect the voltage of the pull-down capacitor node ND_{Cdn}. At this time, the pull-down transmission-gate dnTG conducts the voltage of the pull-down transistor-gating node ND_{NG18} to the pull-down capacitor node ND_{Cdn}.

Next, the description illustrates, with FIGS. 11~14, the operation of the circuit components in the driver portDRV during the rising-transition phase PH1, the high-level stable phase PH2, the falling-transition phase PH3, and the low-level stable phase PH4, respectively. In FIGS. 11-14, transistors and/or transmission-gates in the OFF state are marked with crosses, and dashed arrows indicate the signal transmission direction. For illustrative purposes, the combination of the pull-up path-selection transmission-gate upselTG, the components of the comparison circuit cfCKT, the components of the pull-up circuit upCKT, the pull-up disable transistor updisPM, and the pull-up bypass transistor upbpPM is referred to as the pull-up path; and the combination of the pull-down path-selection transmission-gate dnselTG, the components of the pull-down circuit dnCKT, the pull-down disable transistor dndisNM, and the pull-down bypass transistor dnbpNM is referred to as the pull-down path.

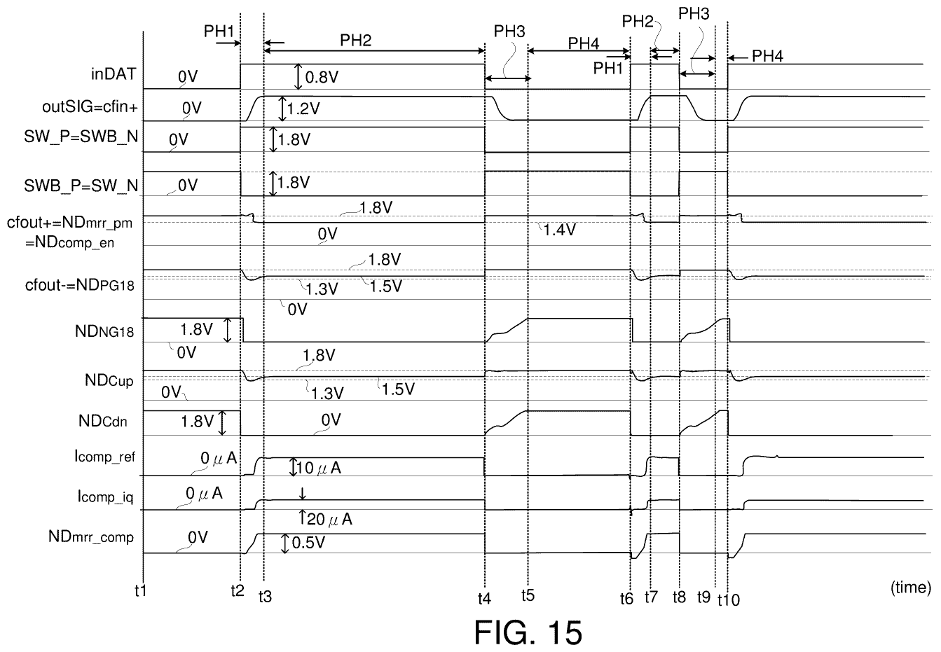

Please refer to FIG. 11, which is a schematic diagram showing the circuit behavior of the driver portDRV during the rising-transition phase PH1 according to the present disclosure. During the rising-transition phase PH1, the driving enable-signal EN is at a high logic-level H (EN=H), and the driver input signal inDAT changes from a low logic-level L to a high logic-level H (inDAT=L→H). FIG. 15 shows the node voltages and signals of the driver portDRV of FIG. 11 (see the rising-transition phase PH1).

Please refer to FIG. 12, which is a schematic diagram showing the circuit behavior of the driver portDRV during the high-level stable phase PH2 according to the present disclosure. Please refer to both FIGS. 10 and 12. During the high-level stable phase PH2, the driving enable-signal EN is at a high logic-level H (EN=H), and the driver input signal inDAT remains at the high logic-level H (inDAT=H). FIG. 15 shows the node voltages and signals of the driver portDRV of FIG. 12 (see the high-level stable phase PH2).

Please refer to FIG. 13, which is a schematic diagram showing the circuit behavior of the driver portDRV during the falling-transition phase PH3 according to the present disclosure. Please refer to both FIGS. 10 and 13. During the falling-transition phase PH3, the driving enable-signal EN is at a high logic-level H (EN=H), and the driver input signal inDAT changes from a high logic-level H to a low logic-level L (inDAT=H→L). FIG. 15 shows the node voltages and signals of the driver portDRV of FIG. 13 (see the falling-transition phase PH3).

Please refer to FIG. 14, which is a schematic diagram showing the circuit behavior of the driver portDRV during the low-level stable phase PH4 according to the present disclosure. Please refer to both FIGS. 10 and 14. During the low-level stable phase PH4, the driving enable-signal EN is at a high logic-level H (EN=H), and the driver input signal inDAT remains at the low logic-level L (inDAT=L). FIG. 15 shows the node voltages and signals of the driver portDRV of FIG. 14 (see the low-level stable phase PH4).

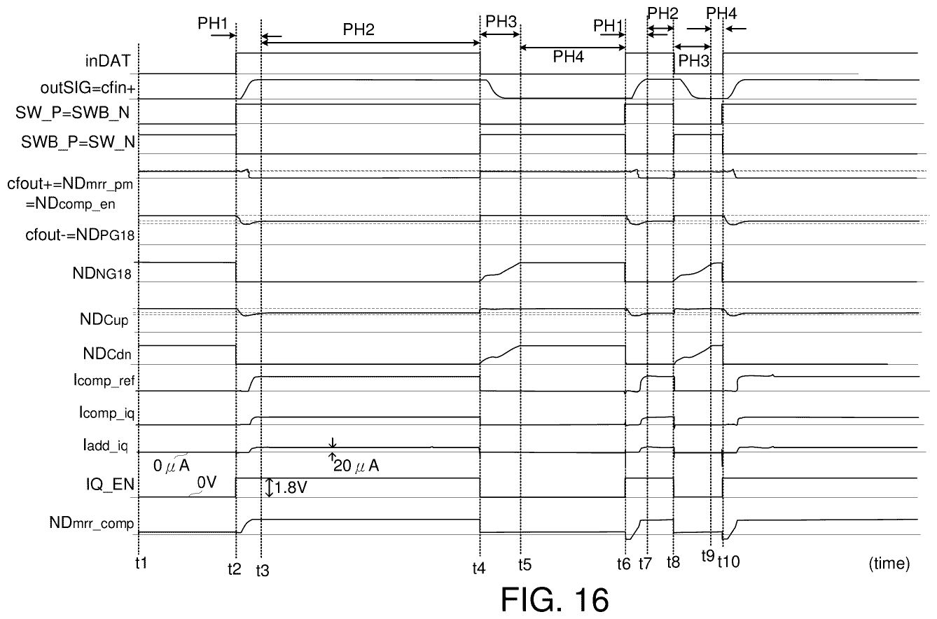

Next, the operation of the driver portDRV at each phase is described with the waveforms of FIGS. 15 and 16. In a concise manner, FIGS. 15 and 16 do not show the waveforms having a constant voltage value, for example, the supply voltage node Vcc, the ground voltage node Gnd, and the inverting input-terminal cfin− of the comparison circuit cfCKT (receiving the reference voltage Vref).

Please refer to FIG. 15, which is a waveform diagram showing the signals on the internal nodes of the driver portDRV of the present disclosure in response to the change of the driver input signal inDAT when the driving enable-signal EN is at a high logic-level H (EN=H) and the external enable-signal IQ_extEN for the additional current-path(s) add_curPATH is set to a low logic-level L (IQ_extEN=L) to disable the additional current-path add_curPATH. The waveforms of FIG. 15 show the changes of the node voltages and signals related to the driver portDRV, including the driver input signal inDAT, the driver output signal outSIG, the positive pull-up switching-signal SW_P, the negative pull-down switching-signal SWB_N, the negative pull-up switching-signal SWB_P, the positive pull-down switching-signal SW_N, the non-inverting output-terminal cfout+ of the comparison circuit cfCKT, the pull-up transistor-gating node ND_{PG18}, the pull-down transistor-gating node ND_{NG18}, the pull-up capacitor node ND_{Cup}, the pull-down capacitor node ND_{Cdn}, the compensation reference current I_{comp_ref}, the compensation current I_{comp_iq}, and the compensation bias node ND_{mrr_comp} during the rising-transition phase PH1, the high-level stable phase PH2, the falling-transition phase PH3 and the low-level stable phase PH4.

Table 3 summarizes the waveform changes in FIG. 15. The voltages and currents listed herein are approximate values for illustrative purposes only. The voltages and currents in actual applications are not limited to these values.

TABLE 3

| | rising-transition | high-level stable | falling-transition | low-level stable |
|---|---|---|---|---|
| Phase | phase PH1 | phase PH2 | phase PH3 | phase PH4 |
| Drawing | FIG. 11 | FIG. 12 | FIG. 13 | FIG. 14 |
| duration | time points | time points | time points | time points |
| | t2~t3, t6~t7 | t3~t4, t7~18 | t4~t5, t8~t9 | t1~t2, t5~t6, |
| | | | | t9~t10 |
| driver input signal inDAT | high logic-level H (0.8 V) | | low logic-level L (0 V) | |
| driver output signal outSIG = | rising from | maintaining | falling from | maintaining |
| non-inverting input-terminal | 0 V to 1.2 V | 1.2 V | 1.2 V to 0 V | 0 V |
| cfin+ of comparison circuit | | | | |
| positive pull-up | high logic-level H | | low logic-level L | |
| switching-signal SW_P = | (1.8 V) | | (0 V) | |
| negative pull-down | | | | |
| switching-signal SWB_N | | | | |
| negative pull-up | low logic-level L | | high logic-level H | |
| switching-signal SWB_P = | (0 V) | | (1.8 V) | |
| positive pull-down | | | | |
| switching-signal SW_N | | | | |
| non-inverting | falling from | maintaining | maintaining | |
| output-terminal cfout+ of | 1.8 V to 1.4 V | 1.4 V | 1.8 V | |
| comparison circuit = | | | | |
| PMOS-current-mirror bias | | | | |
| node NDₘᵣᵣ_{_{—}}ₚₘ = | | | | |
| compensation enable node | | | | |
| ND_{comp}_{_{—}}ₑₙ | | | | |
| inverting output-terminal | falling from | maintaining | maintaining | |
| cfout− of comparison | 1.8 V to 1.3 V, | 1.5 V | 1.8 V | |
| circuit = pull-up transistor- | then rising to | | | |
| gating node ND_{PG18} | 1.5 V | | | |
| pull-down transistor-gating | falling from | maintaining | rising from | maintaining |
| node ND_{NG18} | 1.8 V to 0 V | 0 V | 0 V to 1.8 V | 1.8 V |

| | | | |
|---|---|---|---|
| pull-up capacitor node | falling from | maintaining | maintaining |
| ND_{Cup} | 1.8 V to 1.3 V, | 1.5 V | 1.8 V |
| | then rising to | | |
| | 1.5 V | | |

| | | | |
|---|---|---|---|
| pull-down capacitor node | maintaining | rising from | maintaining |
| ND_{Cdn} | 0 V | 0 V to 1.8 V | 1.8 V |

| | | | |
|---|---|---|---|
| compensation reference | rising from | maintaining | maintaining |
| current I_{comp}_{_{—}}_{ref} | 0 μA to 10 μA | 10 μA | 0 μA |
| compensation current I_{comp}_{_{—}}_{iq} | rising from | maintaining | maintaining |
| | 0 μA to 20 μA | 20 μA | 0 μA |
| compensation bias node | rising from | maintaining | maintaining |
| NDₘᵣᵣ_{_{—}}_{comp} | 0 V to 0.5 V | 0.5 V | 0 V |

In FIG. 15, the period between the time points t2 and t3 and the period between the time points t6 and t7 correspond to the rising-transition phase PH1 (referring to FIG. 11 for the circuit behavior of the driver portDRV during the rising-transition phase PH1); the period between the time points t3 and t4 and the period between the time points t7 and t8 correspond to the high-level stable phase PH2 (referring to FIG. 12 for the circuit behavior of the driver portDRV during the high-level stable phase PH2); the period between the time points t4 and t5 and the period between the time points t8 and t9 correspond to the falling-transition phase PH3 (referring to FIG. 13 for the circuit behavior of the driver portDRV during the falling-transition phase PH3); and the period between the time points t1 and t2, the period between the time points t5 and t6 and the period between the time points t9 and t10 correspond to the low-level stable phase PH4 (referring to FIG. 14 for the circuit behavior of the driver portDRV during the low-level stable phase PH4). Since the driver portDRV cyclically enters the rising-transition phase PH1, the high-level stable phase PH2, the falling-transition phase PH3, and the low-level stable phase PH4, the following description about the waveforms during the time points t2 to t6 can cover all phases.

Please refer to FIGS. 11, 12, and 15 together. In the rising-transition phase PH1 between the time points t2 and t3, the driver input signal inDAT rises from a low logic-level L to a high logic-level H (inDAT=L→H) (see FIG. 11). During the high-level stable phase PH2 between the time points t3 and t4, the driver input signal inDAT remains at a high logic-level H (inDAT=H) (see FIG. 12).

In the rising-transition phase PH1 and the high-level stable phase PH2, the switching-signal generation circuit swGenCKT generates the positive pull-up switching-signal SW_P and the negative pull-down switching-signal SWB_N having a high logic-level H (SW_P=SWB_N=H), and generates the negative pull-up switching-signal SWB_P and the positive pull-down switching-signal SW_N having a low logic-level L (SWB_P=SW_N=L).

Please refer to both FIGS. 11 and 15 together. During the period between the time points t2 and t3, in the pull-up path, because the positive pull-up switching-signal SW_P is at a high logic-level H (SW_P=H), the pull-up path-selection transmission-gate upselTG is turned on, the PMOS-current-mirror disable transistor cfdisPM is turned off, the pull-up disable transistor updisPM is turned off, the pull-up bypass transistor upbpPM is turned off, and the pull-up transmission-gate upTG is turned on.

During the period between the time points t2 and t3, because the negative pull-up switching-signal SWB_P is at a low logic-level L (SWB_P=L), the NMOS-current-mirror disable transistor cfdisNM is turned off. Therefore, the NMOS-current-mirror disable transistor cfdisNM does not affect the voltage of the NMOS-current-mirror bias node ND_{mrr_nm} during the rising-transition phase PH1. At this time, the pull-up path-selection transmission-gate upselTG in the ON state conducts the supply voltage Vcc to the NMOS-current-mirror bias node ND_{mrr_nm}. That is, ND_{mrr_nm}=Vcc.

Since the gate terminals of the positive NMOS-current-mirror transistor nmrr_pNM and the negative NMOS-current-mirror transistor nmrr_nNM are electrically connected to the NMOS-current-mirror bias node ND_{mrr_nm}, the positive NMOS-current-mirror transistor nmrr_pNM and the negative NMOS-current-mirror transistor nmrr_nNM are turned on when the NMOS-current-mirror bias node ND_{mrr_nm} is set to the supply voltage Vcc (ND_{mrr_nm}=Vcc). In addition, the reference current Iref (10 μA, for example) provided by the reference current source curSRC becomes the bias reference current I_{pNM} flowing to the ground voltage Gnd through the positive NMOS-current-mirror transistor nmrr_pNM. Based on the current-mirror architecture, a bias mirror current I_{nNM} (40 μA, for example) also flows through the negative NMOS-current-mirror transistor nmrr_nNM.

On the other hand, since the PMOS-current-mirror disable transistor cfdisPM is turned off due to the positive pull-up switching-signal SW_P (SW_P=H), the PMOS-current-mirror disable transistor cfdisPM does not affect the voltage of the PMOS-current-mirror bias node ND_{mrr_pm} (also, to the non-inverting output-terminal cfout+ of the comparison circuit cfCKT). At this time, whether the positive PMOS-current-mirror transistor pmrr_pPM and the negative PMOS-current-mirror transistor pmrr_nPM are turned on or off depends on the voltage of the PMOS-current-mirror bias node ND_{mrr_pm} (also, the non-inverting output-terminal cfout+ of the comparison circuit cfCKT).

In the comparison circuit cfCKT, the negative differential-input transistor diffnNM is turned on because its gate terminal (equivalent to the inverting input-terminal cfin− of the comparison circuit cfCKT) receives the reference voltage Vref. Thus, the voltage of the inverting output-terminal cfout− of the comparison circuit cfCKT (also, the voltage of the pull-up transistor-gating node ND_{PG18}) gradually falls from the voltage value of the supply voltage Vcc to about 1.3V (cfout−=ND_{PG18}=Vcc↓).

Consequentially, during the period between the time points t2 and t3, the PMOS-current-mirror bias node ND_{mrr_pm}, symmetric to the inverting output-terminal cfout− of the comparison circuit cfCKT, has the voltage (that is, the voltage of the non-inverting output-terminal cfout+ of the comparison circuit cfCKT) gradually falling from the supply voltage Vcc to about 1.4V (cfout+=ND_{mrr_pm}=ND_{comp_en}=Vcc→1.4V) when the positive differential-input transistor diffpNM and the negative NMOS-current-mirror transistor nmrr_nNM are turned on.

According to the gradually decreasing voltage of the non-inverting output-terminal cfout+ of the comparison circuit cfCKT, the positive PMOS-current-mirror transistor pmrr_pPM will be turned on to generate a current (20 μA, for example) flowing through the positive PMOS-current-mirror transistor pmrr_pPM and the positive differential-input transistor diffpNM. Since the PMOS-current-mirror bias node ND_{mrr_pm} is electrically connected to the non-inverting output-terminal cfout+ of the comparison circuit cfCKT, the negative PMOS-current-mirror transistor pmrr_nPM will also be turned on. The negative PMOS-current-mirror transistor pmrr_nPM in the ON state slightly pulls up the voltage of the inverting output-terminal cfout− of the comparison circuit cfCKT (also, the voltage of the pull-up transistor-gating node ND_{PG18}) from 1.3V to 1.5V. Thereafter, the negative PMOS-current-mirror transistor pmrr_nPM, the negative differential-input transistor diffnNM, and the negative NMOS-current-mirror transistor nmrr_nNMin the ON state will make the pull-up transistor-gating node ND_{PG18} remain at approximately 1.5V.

At this time, a current (20 μA, for example) is generated and flowing through the negative PMOS-current-mirror transistor pmrr_nPM and the negative differential-input transistor diffnNM. Furthermore, the current flowing through the negative NMOS-current-mirror transistor nmrr_nNM is equivalent to the sum of the current flowing through the negative differential-input transistor diffnNM and the current flowing through the positive differential-input transistor diffpNM (40 μA, for example).

In the pull-up circuit upCKT, the gate terminal of the pull-up transistor upPM is controlled by the voltage of the pull-up transistor-gating node ND_{PG18}. As described above, the voltage of the pull-up transistor-gating node ND_{PG18} is equivalent to the inverting output-terminal cfout− of the comparison circuit cfCKT (ND_{PG18}=cfout−). Therefore, the voltage of the pull-up transistor-gating node ND_{PG18} first gradually falls from the supply voltage Vcc to 1.3V, and then slightly rises to 1.5V. That is, ND_{PG18}=cfout−=1.8V→1.3V→1.5V.

As the voltage of the pull-up transistor-gating node ND_{PG18} changes, the state of the pull-up transistor upPM changes from the OFF state to the ON state, and the voltage of the driver output signal outSIG is gradually pulled up from the ground voltage Gnd during the period between the time points t2 and t3. In addition, because the compensation current I_{comp_iq} is generated in the compensation current-path comp_curPATH, the voltage of the driver output signal outSIG is simultaneously pulled down by the compensation current-path comp_curPATH. Therefore, the driver output signal outSIG still does not rise to the supply voltage Vcc at the time t3, but only rises to the reference voltage Vref. That is, outSIG=Gnd→Vref.

Since the pull-up transmission-gate upTG is turned on due to the high logic-level H of the positive pull-up switching-signal SW_P (SW_P=H), the voltage of the pull-up capacitor node ND_{Cup} is equivalent to the voltage of the inverting output-terminal cfout− of the comparison circuit cfCKT during the period between the time points t2 and t3. Therefore, the voltage of the pull-up capacitor node ND_{Cup} also falls from 1.8V to 1.3V and then rises from 1.3V to 1.5V during the period between the time points t2 and t3. That is, ND_{Cup}=1.8V→1.3V→1.5V. During this period, the pull-up capacitor Cup is also charged through the negative PMOS-current-mirror transistor pmrr_nPM, the pull-up transistor-gating node ND_{PG18}, the pull-up transmission-gate upTG, and the pull-up capacitor node ND_{Cup}.

In the pull-down path, because the positive pull-down switching-signal SW_N is at a low logic-level L (SW_N=L), the pull-down path-selection transmission-gate dnselTG and the pull-down transmission-gate dnTG are turned off. On the other hand, because the negative pull-down switching-signal SWB_N is at a high logic-level H (SWB_N=H), the pull-down bypass transistor dnbpNM and the pull-down disable transistor dndisNM are turned on.

As the pull-down disable transistor dndisNM is turned on, the pull-down disable transistor dndisNM conducts the ground voltage Gnd to the pull-down transistor-gating node ND_{NG18}, so the voltage of the pull-down transistor-gating node ND_{NG18} is equivalent to the ground voltage Gnd. That is, ND_{NG18}=Gnd. Thus, the pull-down transistor dnNM is turned off because the gate terminal thereof connected to the pull-down transistor-gating node ND_{NG18} has a voltage equivalent to the ground voltage Gnd (ND_{NG18}=Gnd). Therefore, in FIG. 11, the pull-down transistor dnNM does not affect the driver output signal outSIG. In addition, because the pull-down bypass transistor dnbpNM is turned on, the pull-down capacitor node ND_{Cdn} is pulled down to the ground voltage Gnd.

In the compensation circuit compCKT of FIG. 11, because the positive pull-up switching-signal SW_P is at a high logic-level H (SW_P=H), the compensation current-path enable transistor comp_iqenNM is turned on. And, because the negative pull-up switching-signal SWB_P is at a low logic-level L (SWB_P=L), the compensation disable transistor comp_disNM is turned off. The compensation disable transistor comp_disNM in the OFF state does not affect the voltage of the compensation bias node ND_{mrr_comp}.

On the other hand, because the gate terminal of the compensation pull-up bias transistor comp_bspPM for the compensation reference current I_{comp_ref} is electrically connected to the non-inverting output-terminal cfout+ of the comparison circuit cfCKT, whether the compensation pull-up bias transistor comp_bspPM is turned on or off depends on the voltage of the non-inverting output-terminal cfout+ of the comparison circuit cfCKT (cfout+=ND_{mrr_pm}=ND_{comp_en}).

Since the voltage of the non-inverting output-terminal cfout+ of the comparison circuit cfCKT gradually falls from the supply voltage Vcc to 1.4V (cfout+=ND_{mrr_pm}=ND_{comp_en}=Vcc→1.4V), the ON/OFF state of the compensation pull-up bias transistor comp_bspPM for the compensation reference current I_{comp_ref} gradually changes from the OFF state to an ON state. The compensation pull-up bias transistor comp_bspPM in the ON state conducts the supply voltage Vcc to the compensation bias node ND_{mrr_comp}. Therefore, the voltage of the compensation bias node ND_{mrr_comp} gradually increases.

With the increasing voltage of the compensation bias node ND_{mrr_comp}, the compensation pull-down bias transistor comp_bsnNM for the compensation reference current I_{comp_ref} and the compensation current-path transistor comp_iqNM are also turned on. As the compensation pull-up bias transistor comp_bspPM for the compensation reference current I_{comp_ref} is gradually turned on, a compensation reference current I_{comp_ref} (10 μA, for example) is generated in the compensation reference current-path comp_refPATH and flows through the compensation pull-up bias transistor comp_bspPM and the compensation pull-down bias transistor comp_bsnNM for the compensation reference current I_{comp_ref}. Since both the compensation pull-up bias transistor comp_bspPM and the compensation pull-down bias transistor comp_bsnNM are turned on, the voltage of the compensation bias node ND_{mrr_comp} rises from the ground voltage Gnd to about 0.5V during the period between the time points t2 and t3.

The compensation bias node ND_{mrr_comp} is equivalent to 0.5V (ND_{mrr_comp}=0.5V). At this time, the compensation current-path transistor comp_iqNM, which forms the current-mirror with the compensation pull-down bias transistor comp_bsnNM for the compensation reference current I_{comp_ref}, is also turned on because the gate terminal thereof is connected to the compensation bias node ND_{mrr_comp}. In addition, because the compensation current-path enable transistor comp_iqenNM is turned on due to the high logic-level of the positive pull-up switching-signal SW_P (SW_P=H), the compensation current I_{comp_iq} (20 μA, for example) is generated in the compensation current-path comp_curPATH and flows through the compensation current-path enable transistor comp_iqenNM and the compensation current-path transistor comp_iqNM. Since the drain terminal of the compensation current-path enable transistor comp_iqenNM is electrically connected to the driver output node NDₒᵤₜ, the compensation current-path enable transistor comp_iqenNM conducts the ground voltage Gnd to the driver output node NDₒᵤₜ, so the voltage of the driver output signal outSIG is pulled down because of the generation of the compensation current I_{comp_iq}.

As described above, in FIG. 11, the driver output signal outSIG is pulled up due to the ON state of the pull-up transistor upPM, and is pulled down due to the ON state of the compensation current-path enable transistor comp_iqenNM and the compensation current-path transistor comp_iqNM. Thus, the voltage of the driver output signal outSIG is within the range between the ground voltage Gnd and the supply voltage Vcc. At this time, based on the symmetric structure of the PMOS current-mirror pMRR, the voltage of the driver output signal outSIG is equivalent to the reference voltage Vref.

Continuing with the previous point, in FIG. 11, the driver output signal outSIG rises from the ground voltage Gnd to the reference voltage Vref. That is, outSIG=Gnd→Vref=0V→1.2V. In addition, in FIG. 11, the driving enable transmission-gate enTG is turned on due to the high logic-level H of the driving enable-signal EN (EN=H), so the voltage of the capacitor feedback node ND_{Cfb} changes with the output signal outSIG. That is, ND_{Cfb}=0V→1.2V.

When the driver portDRV is in the rising-transition phase PH1, it is not only using the pull-up transistor upPM to pull up the voltage of the driver output signal outSIG, but also charging the pull-up capacitor Cup through the pull-up transmission-gate upTG. Thus, the pull-up transistor-gating node ND_{PG18} is also affected by this voltage conduction path. Accordingly, the setting of the pull-up capacitor Cup can compensate for the AC response of the driver output signal outSIG during the period between the time points t2 and t3.

Continuing with the previous point, the Miller effect of the pull-up capacitor Cup affects the slew rate of the driver output signal outSIG. The larger capacitance value the pull-up capacitor Cup has, the lower slew rate and the smoother voltage rising the driver output signal outSIG presents. Conversely, the smaller capacitance value the pull-up capacitor Cup has, the higher slew rate and the sharper voltage rising the driver output signal outSIG presents in the rising-transition phase PH1. In actual applications, the capacitance value selected for the pull-up capacitor Cup depends on the specifications required by the driver portDRV.

During the period between the time points t3 and t4 (the high-level stable phase PH2, see FIG. 12), the driver input signal inDAT remains at a high logic-level H (inDAT=H). Therefore, the ON/OFF states of the transistors in the driver portDRV in FIG. 12 remain as they are in FIG. 11. Moreover, during the period between the time points t3 and t4, the driver output signal outSIG, the positive pull-up switching-signal SW_P, the negative pull-down switching-signal SWB_N, the negative pull-up switching-signal SWB_P, the positive pull-down switching-signal SW_N, the non-inverting output-terminal cfout+ of the comparison circuit cfCKT, the pull-up transistor-gating node ND_{PG18}, the pull-down transistor-gating node ND_{NG18}, the pull-up capacitor node ND_{Cup}, the pull-down capacitor node ND_{Cdn}, the compensation reference current I_{comp_ref}, the compensation current I_{comp_iq} and the compensation bias node ND_{mrr_comp} maintain their voltages/currents as they are at the time point t3. Thus, the details about the ON/OFF states of the transistors in the driver portDRV and the voltages of the nodes in FIG. 12 will not be repeated here.

Please refer to FIGS. 13, 14, and 15. In the falling-transition phase PH3, the driver input signal inDAT falls from a high logic-level H to a low logic-level L (inDAT=H→L). During the low-level stable phase PH4, the driver input signal inDAT remains at a low logic-level L (inDAT=L). In the falling-transition phase PH3 and the low-level stable phase PH4, the switching-signal generation circuit swGenCKT generates the positive pull-up switching-signal SW_P and the negative pull-down switching-signal SWB_N having a low logic-level L (SW_P=SWB_N=L), and generates the negative pull-up switching-signal SWB_P and the positive pull-down switching-signal SW_N having a high logic-level H (SWB_P=SW_N=H). The circuit behavior related to the pull-up path, the pull-down path, and the compensation circuit compCKT will be sequentially described.

Please refer to both FIGS. 13 and 15. During the period between the time points t4 and t5, in the pull-up path, because the positive pull-up switching-signal SW_P is at a low logic-level L (SW_P=L), the pull-up path-selection transmission-gate upselTG is turned off, the PMOS-current-mirror disable transistor cfdisPM is turned on, the pull-up disable transistor updisPM is turned on, the pull-up bypass transistor upbpPM is turned on, and the pull-up transmission-gate upTG is turned off. Because the negative pull-up switching-signal SWB_P is at a high logic-level H (SWB_P=H), the NMOS-current-mirror disable transistor cfdisNM is turned on.

Because the NMOS-current-mirror disable transistor cfdisNM is turned on, the NMOS-current-mirror disable transistor cfdisNM conducts the ground voltage Gnd to the NMOS-current-mirror bias node ND_{mrr_nm}. That is, ND_{mrr_nm}=Gnd. Therefore, the positive NMOS-current-mirror transistor nmrr_pNM and the negative NMOS-current-mirror transistor nmrr_nNM are turned off because the gate terminals thereof are connected to the NMOS-current-mirror bias node ND_{mrr_nm} having a voltage equivalent to the ground voltage Gnd (ND_{mrr_nm}=Gnd).

In the comparison circuit cfCKT, when the voltage of the NMOS-current-mirror bias node ND_{mrr_nm} is set to the ground voltage Gnd (ND_{mrr_nm}=Gnd), the positive NMOS-current-mirror transistor nmrr_pNM and the negative NMOS-current-mirror transistor nmrr_nNM are turned off. In addition, when the PMOS-current-mirror disable transistor cfdisPM is turned on, the PMOS-current-mirror disable transistor cfdisPM conducts the supply voltage Vcc to the PMOS-current-mirror bias node ND_{mrr_pm}, so the voltage of the non-inverting output-terminal cfout+ of the comparison circuit cfCKT is equivalent to the supply voltage Vcc (cfout+=ND_{mrr_pm}=ND_{comp_en}=Vcc). At this time, the positive PMOS-current-mirror transistor pmrr_pPM and the negative PMOS-current-mirror transistor pmrr_nPM are turned off because the gate terminals thereof receive the supply voltage Vcc.

As shown in FIG. 13, the pull-up disable transistor updisPM is turned on due to SW_P=L. The pull-up disable transistor updisPM in the ON state conducts the supply voltage Vcc to the pull-up transistor-gating node ND_{PG18}. That is, ND_{PG18}=Vcc. Also, the pull-up transistor upPM is turned off when the voltage of the pull-up transistor-gating node ND_{PG18} is equivalent to the supply voltage Vcc. At this time, the pull-up transistor upPM does not affect the driver output signal outSIG. In addition, during the period between the time points t4 and t5, because the pull-up bypass transistor upbpPM is turned on, the voltage of the pull-up capacitor node ND_{Cup} is equivalent to the supply voltage Vcc. That is, ND_{Cup}=1.8V. And, the pull-up capacitor Cup is continuously charged to 1.8V through the pull-up bypass transistor upbpPM and the pull-up capacitor node ND_{Cup} during the period between the time points t4 and t5.

In the pull-down path, because the positive pull-down switching-signal SW_N is at a high logic-level H (SW_N=H), the pull-down path-selection transmission-gate dnselTG and the pull-down transmission-gate dnTG are turned on. Because the negative pull-down switching-signal SWB_N is at a low logic-level L (SWB_N=L), the pull-down bypass transistor dnbpNM and the pull-down disable transistor dndisNM are turned off.

Since the pull-down disable transistor dndisNM is turned off, the pull-down disable transistor dndisNM does not affect the voltage of the pull-down transistor-gating node ND_{NG18}. At this time, the pull-down path-selection transmission-gate dnselTG in the ON state conducts the supply voltage Vcc to the pull-down transistor-gating node ND_{NG18}. The voltage of the pull-down transistor-gating node ND_{NG18} rises from the ground voltage Gnd to the supply voltage Vcc during the period between the time points t4 and t5. That is, ND_{NG18}=Gnd→Vcc. Thus, the pull-down transistor dnNM is turned on because the gate terminal thereof is connected to the pull-down transistor-gating node ND_{NG18} having a voltage equivalent to the supply voltage Vcc, thereby causing the driver output signal outSIG to fall from the supply voltage Vcc to the ground voltage Gnd. That is, outSIG=Vcc→Gnd.

During the period between the time points t4 and t5, because the pull-down transmission-gate dnTG is turned on, the voltage of the pull-down capacitor node ND_{Cdn} rises to the supply voltage Vcc synchronously with the pull-down transistor-gating node ND_{NG18}.

In the compensation circuit compCKT, because the negative pull-up switching-signal SWB_P is at a high logic-level H (SWB_P=H), the compensation disable transistor comp_disNM is turned on. Moreover, the compensation disable transistor comp_disNM sets the compensation bias node ND_{mrr_comp} to the ground voltage Gnd (ND_{mrr_comp}=Gnd). Thus, the compensation pull-down bias transistor comp_bsnNM for the compensation reference current I_{comp_ref} and the compensation current-path transistor comp_iqNM maintain the OFF state during the period between the time points t4 and t5.

Whether the compensation pull-up bias transistor comp_bspPM for the compensation reference current I_{comp_ref} is turned on or off depends on the voltage of the PMOS-current-mirror bias node ND_{mrr_pm} (equivalent to the non-inverting output-terminal cfout+ of the comparison circuit cfCKT) (cfout+=ND_{mrr_pm}=ND_{comp_en}). In addition, in FIG. 13, because the voltage of the non-inverting output-terminal cfout+ of the comparison circuit cfCKT is equivalent to the supply voltage Vcc, the compensation pull-up bias transistor comp_bspPM for the compensation reference current I_{comp_ref} remains turned off during the period between the time points t4 and t5. Therefore, during the period between the time points t4 and t5, no compensation reference current I_{comp_ref} is generated in the compensation reference current-path comp_refPATH. On the other hand, in the compensation current-path comp_curPATH, the compensation current-path enable transistor comp_iqenNM is turned off because the positive pull-up switching-signal SW_P is at a low logic-level L (SW_P=L). Therefore, in the compensation current-path comp_curPATH, both the compensation current-path enable transistor comp_iqenNM and the compensation current-path transistor comp_iqNM are turned off. At this time, no compensation current I_{comp_iq} is generated in the compensation current-path comp_curPATH.

In addition, in FIG. 13, the driver output signal outSIG is pulled down to the ground voltage Gnd when the pull-down transistor dnNM is turned on. Therefore, the positive differential-input transistor diffpNM in the differential input circuit difflnCKT is turned off because the gate terminal thereof receives the driver output signal outSIG equivalent to the ground voltage Gnd. Thus, the negative differential-input transistor diffnNM on the other side of the differential input circuit difflnCKT is also turned off in the falling-transition phase PH3.

When the driver portDRV is in the falling-transition phase PH3, it is not only using the pull-down transistor dnNM to pull down the voltage of the driver output signal outSIG, but also charging the pull-down capacitor Cdn through the pull-down transmission-gate dnTG. Thus, the pull-down transistor-gating node ND_{NG18} is also affected by this voltage conduction path. Accordingly, the setting of the pull-down capacitor Cdn can compensate for the AC response of the driver output signal outSIG during the period between the time points t4 and t5.

Continuing with the previous point, the Miller effect of the pull-down capacitor Cdn affects the slew rate of the driver output signal outSIG. The large capacitance value of the pull-down capacitor Cdn results in the lower slew rate, and the smoother voltage falling of the driver output signal outSIG presents. Conversely, the smaller capacitance value the pull-down capacitor Cdn has, the higher slew rate and the sharper voltage falling the driver output signal outSIG presents in the falling-transition phase PH3. In actual applications, the capacitance value selected for the pull-down capacitor Cdn depends on the specifications required by the driver portDRV.

During the period between the time points t5 and t6 (the low-level stable phase PH4, see FIG. 14), the driver input signal inDAT remains at a low logic-level L (inDAT=L). Therefore, the ON/OFF states of the transistors in the driver portDRV in FIG. 14 remain as they are in FIG. 13. Moreover, during the period between the time points t5 and t6, the driver output signal outSIG, the positive pull-up switching-signal SW_P, the negative pull-down switching-signal SWB_N, the non-inverting output-terminal cfout+ of the comparison circuit cfCKT, the pull-up transistor-gating node ND_{PG18}, the pull-down transistor-gating node ND_{NG18}, the pull-up capacitor node ND_{Cup}, the pull-down capacitor node ND_{Cdn}, the compensation reference current I_{comp_ref}, the compensation current I_{comp_iq} and the compensation bias node ND_{mrr_comp} maintain their voltages/currents as they are at the time point t5. Thus, the details about the ON/OFF states of the transistors in the driver portDRV and the voltages of the nodes in FIG. 14 will not be repeated here.

As described above, the external enable-signal IQ_extEN for the additional current-path(s) add_curPATH is an input of the additional current-path enable circuit addEnCKT. Another input of the additional current-path enable circuit addEnCKT is the positive pull-up switching-signal SW_P. In an embodiment, the additional current-path enable circuit addEnCKT is implemented by an AND gate.

When the external enable-signal IQ_extEN for the additional current-path(s) add_curPATH is at a low logic-level L (IQ_extEN=L), regardless of the logic-level of the positive pull-up switching-signal SW_P, the additional current-path enable-signal IQ_EN output by the AND gate remains at a low logic-level L (IQ_EN=L). The waveforms of FIG. 15 correspond to the condition that the additional current-path add_curPATH in FIG. 5 is disabled. In other words, the waveforms in FIG. 15 correspond to the states of the driver portDRV in FIGS. 11-14.

On the other hand, when the external enable-signal IQ_extEN for the additional current-path(s) add_curPATH is at a high logic-level H (IQ_extEN=H), the additional current-path enable-signal IQ_EN output by the AND gate changes with the logic-level of the positive pull-up switching-signal SW_P. When the positive pull-up switching-signal SW_P is at a high logic-level H (SW_P=H), the additional current-path enable-signal IQ_EN is also at a high logic-level H (IQ_EN=(IQ_extEN AND SW_P)=H). When the positive pull-up switching-signal SW_P is at a low logic-level L (SW_P=L), the additional current-path enable-signal IQ_EN is also at a low logic-level L (IQ_EN=L). FIG. 16 is a waveform diagram showing that the signals in the condition that external enable-signal IQ_extEN for the additional current-path(s) add_curPATH remains at the high logic-level H (IQ_extEN=(IQ_extEN AND SW_P)=H), so the additional current-path enable-signal IQ_EN is at a high logic-level H (IQ_EN=H) during the rising-transition phase PH1 and the high-level stable phase PH2 to enable the additional current-path.

Please refer to FIG. 16, which is a waveform diagram showing the signals on the internal nodes of the driver portDRV of the present disclosure in response to the driver input signal inDAT when the driving enable-signal EN is at a high logic-level H (EN=H) and the external enable-signal IQ_extEN for the additional current-path(s) add_curPATH is set to a high logic-level H (IQ_extEN=H) to enable the additional current-path add_curPATH.

The signal waveforms in FIG. 15 and FIG. 16 are substantially similar to each other. The difference between the two is that the additional current I_{add_iq} and the additional current-path enable-signal IQ_EN are added in the waveforms in FIG. 16 because the external enable-signal IQ_extEN for the additional current-path(s) add_curPATH is at a high logic-level H (IQ_extEN=H). In other words, the condition of FIG. 15 could be considered as a case in which the additional current I_{add_iq} maintains 0 μA and the additional current-path enable-signal IQ_EN remains at a low logic-level L (IQ_EN=L).

With the generation of the additional current I_{add_iq}, some signals change in a smoother manner. For example, by comparing the voltage waveforms of the compensation bias node ND_{mrr_comp} in FIGS. 15 and 16, it can be seen that the voltage waveform of the compensation bias node ND_{mrr_comp} in the period between the time points t2 and t3 (the rising-transition phase PH1) in FIG. 16 is slightly smoother than the corresponding voltage waveform in FIG. 15, even though the voltage of the compensation bias node ND_{mrr_comp} rises from 0V to 0.5V in both FIGS. 15 and 16.

The voltage waveforms of other nodes, such as the non-inverting output-terminal cfout+ of the comparison circuit cfCKT, the inverting output-terminal cfout− of the comparison circuit cfCKT, and the pull-up capacitor node ND_{Cup} in FIG. 16 present smoother or smaller changes than those in FIG. 15. It is obtained that the introduced additional current I_{add_iq} does not change the signal trend, but smooths the signal change during the rising-transition phase PH1. In this situation, the signals in FIG. 16, which have been described with reference to FIG. 15 will not be described again here.

Table 4 summarizes the waveforms of the new signals in FIG. 16 and their change trends in the phases. The voltages and currents listed here are approximate values for reference only, and the values in actual applications are not limited to the examples.

TABLE 4

| | rising-transition | high-level stable | falling-transition | low-level stable |
|---|---|---|---|---|
| Phase | phase PH1 | phase PH2 | phase PH3 | phase PH4 |
| Drawing | FIG. 11 | FIG. 12 | FIG. 13 | FIG. 14 |
| additional | Rising from | maintaining | maintaining | |
| current I_{add}_{_{—}}_{iq} | 0 μA to 20 μA | 20 μA | 0 μA | |
| additional | high logic-level H | | Low logic-level L | |
| current-path | (1.8 V) | | (0 V) | |
| enable-signal | | | | |
| IQ_EN | | | | |

Please refer to both FIG. 16 and Table 4. Because the positive pull-up switching-signal SW_P is at a high logic-level H (SW_P=H) during the rising-transition phase PH1 and the high-level stable phase PH2, the additional current-path enable-signal IQ_EN is also at a high logic-level H (IQ_EN=H) during the rising-transition phase PH1 and the high-level stable phase PH2. Moreover, the current value of the additional current I_{add_iq} rises from 0 μA to 20 μA in the rising-transition phase PH1, and then remains at 20 μA during the high-level stable phase PH2. During the falling-transition phase PH3 and the low-level stable phase PH4, the additional current-path enable-signal IQ_EN is at a low logic-level L (IQ_EN=L), and no additional current I_{add_iq} is generated at this time.

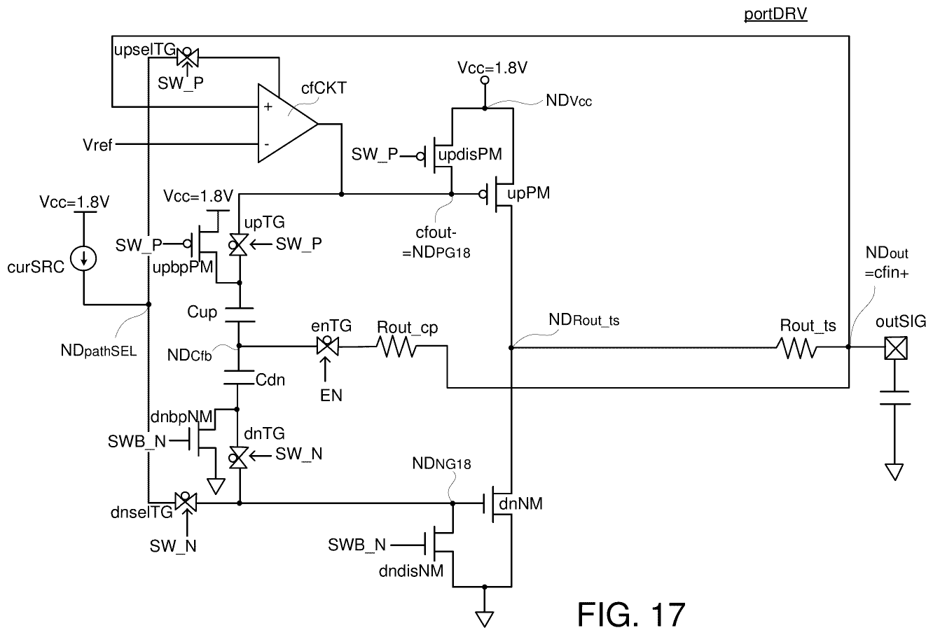

Please refer to FIG. 17, which is a schematic diagram illustrating a driver portDRV with a transistor-path output impedance Rout_ts and a capacitor-path output impedance Rout_cp. Please note that the term “impedance” in the present disclosure may represent either the impedance element or the impedance value, and the actual meaning depends on the context. In this diagram, the transistor-path output impedance Rout_ts (Rout_ts=500Ω for example) is electrically connected between the transistor-path output node ND_{Rout_ts} and the driver output node NDₒᵤₜ; and the capacitor-path output impedance Rout_cp (Rout_cp=2500 for example) is electrically connected between the driving enable transmission-gate enTG and the driver output node NDₒᵤₜ. The transistor-path output impedance Rout_ts is greater than the capacitor-path output impedance Rout_cp. In actual applications, the impedance values of the transistor-path output impedance Rout_ts and the capacitor-path output impedance Rout_cp are not limited to the examples.

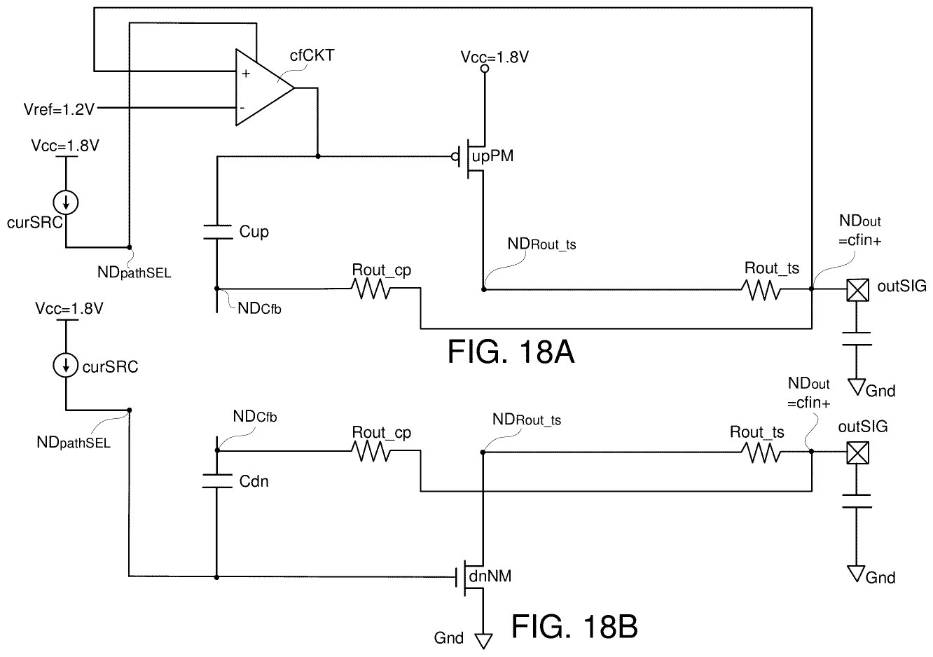

Please refer to FIG. 18A, which is a schematic diagram for calculating the equivalent output impedance Rout_eq of the driver portDRV with the transistor-path output impedance Rout_ts and the capacitor-path output impedance Rout_cp added, wherein the pull-up path is selected in the rising-transition phase PH1 and the high-level stable phase PH2. Please refer to FIGS. 11, 12, and 18A together.

When the driver portDRV enters the rising-transition phase PH1 or the high-level stable phase PH2, calculating the equivalent output impedance Rout_eq should consider the pull-up output impedances Rout_up1 and Rout_up2 in the two signal pull-up transmission paths. The pull-up output impedance Rout_up1 of the signal pull-up transmission path (Rout_ts+upPM) covers the transistor-path output impedance Rout_ts and the pull-up transistor upPM connected in series. The pull-up output impedance Rout_up2 of the signal pull-up transmission path (Rout_cp+Cup) covers the capacitor-path output impedance Rout_cp and the pull-up capacitor Cup connected in series.

Since the signal pull-up transmission paths (Rout_ts+upPM) and (Rout_cp+Cup) are parallel to each other, the equivalent output impedance Rout_eq of the driver portDRV in FIG. 18A is expressed as the parallel connection of the pull-up output impedances Rout_up1 and Rout_up2. That is, Rout_eq=Rout_up1//Rout_up2. In the signal pull-up transmission path (Rout_ts+upPM), since the pull-up transistor upPM has a very small turn-on resistance when it is turned on, the pull-up output impedance Rout_up1 approximates the transistor-path output impedance Rout_ts. That is, Rout_up1≈Rout_ts. In addition, since the impedance of the pull-up capacitor Cup is equivalent to infinity (∞), the pull-up output impedance Rout_up2 of the signal pull-up transmission path (Rout_cp+Cup) approximates infinity (∞). That is, Rout_up2≈∞. Accordingly, in FIG. 18A, the equivalent output impedance Rout_eq is equivalent to the parallel connection of the pull-up output impedances Rout_up1 and Rout_up2 of the signal pull-up transmission paths (Rout_ts+upPM) and (Rout_cp+Cup). At this time, the equivalent output impedance Rout_eq approximates the transistor-path output impedance Rout_ts. That is, Rout_eq=Rout_up1//Rout_up2≈Rout_ts.

Please refer to FIG. 18B, which is a schematic diagram for calculating the equivalent output impedance Rout_eq of the driver portDRV with the transistor-path output impedance Rout_ts and the capacitor-path output impedance Rout_cp added, wherein the pull-down path is selected in the falling-transition phase PH3 and the low-level stable phase PH4. Please refer to FIGS. 13, 14, and 18B together.

When the driver portDRV enters the falling-transition phase PH3 or the low-level stable phase PH4, calculating the equivalent output impedance Rout_eq should consider the pull-down output impedances Rout_dn1 and Rout_dn2 in two signal pull-down transmission paths. The pull-down output impedance Rout_dn1 of the signal pull-down transmission path (Rout_ts+dnNM) covers the transistor-path output impedance Rout_ts and the pull-down transistor dnNM connected in series. The pull-down output impedance Rout_dn2 of the signal pull-down transmission path (Rout_cp+Cdn) covers the capacitor-path output impedance Rout_cp and the pull-down capacitor Cdn connected in series. Since the signal pull-down transmission paths (Rout_ts+dnNM) and (Rout_cp+Cdn) are parallel to each other, the equivalent output impedance Rout_eq of the driver portDRV in FIG. 18B is expressed as the parallel connection of the pull-down output impedances Rout_dn1 and Rout_dn2. That is, Rout_eq=Rout_dn1//Rout_dn2.

In the signal pull-down transmission path (Rout_ts+dnNM), since the pull-down transistor dnNM has a very small turn-on resistance when it is turned on, the pull-down output impedance Rout_dn1 approximates the transistor-path output impedance Rout_ts. That is, Rout_dn1≈Rout_ts. In addition, since the impedance of the pull-down capacitor Cdn is equivalent to infinity (∞), the pull-down output impedance Rout_dn2 of the signal pull-down transmission path (Rout_cp+Cdn) approximates infinity (∞). That is, Rout_dn2≈∞. Accordingly, in FIG. 18B, the equivalent output impedance Rout_eq is equivalent to the parallel connection of the pull-down output impedances Rout_dn1 and Rout_dn2 of the signal pull-down transmission paths (Rout_ts+dnNM) and (Rout_cp+Cdn). At this time, the equivalent output impedance Rout_eq approximates the transistor-path output impedance Rout_ts. That is, Rout_eq=Rout_dn1//Rout_dn2≈Rout_ts.

In actual applications, the driver portDRV of the present disclosure may set K pull-up transistors upPM[1]~upPM[K] in the pull-up circuit upCKT, and set K pull-down transistors dnNM[1]~dnNM[K] in the pull-down circuit dnCKT for the consideration of electrostatic discharge (ESD) protection. The variable K is a positive integer. It is supposed that K=4 in the following example.

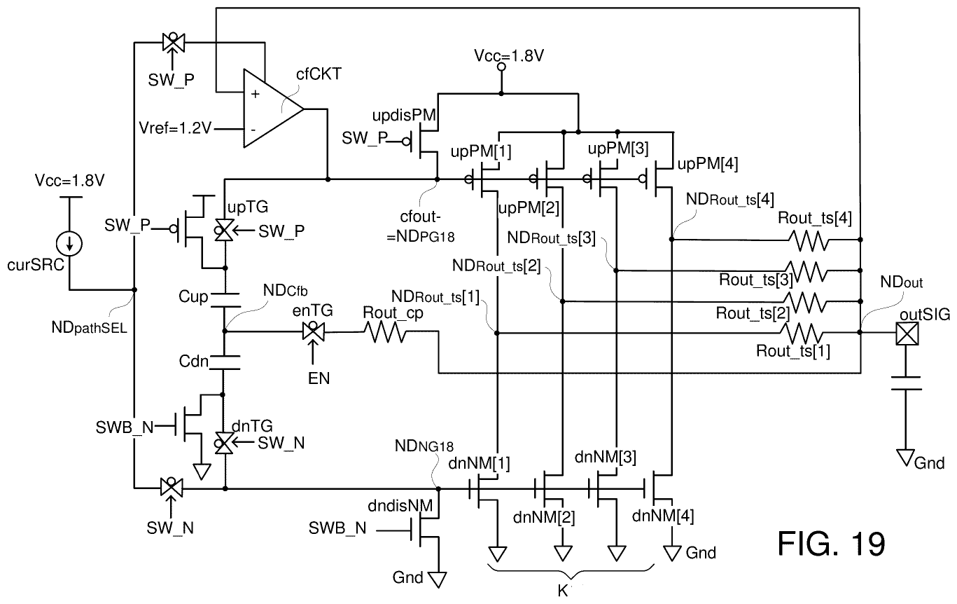

Please refer to FIG. 19, which is a schematic diagram illustrating that plural pull-up transistors upPM[1]~upPM[4], plural pull-down transistors dnNM[1]~dnNM[4], and plural transistor-path output impedances Rout_ts[1]~Rout_ts[4] are provided and arranged in parallel in a driver portDRV. The pull-up circuit upCKT includes the pull-up transistors upPM[1]~upPM[4] connected in parallel, and the pull-down circuit dnCKT includes the pull-down transistors dnNM[1]-dnNM[4] connected in parallel.

The source terminals of the pull-up transistors upPM[1]~upPM[4] are all electrically connected to the supply voltage node Vcc, and the gate terminals are all electrically connected to the pull-up transistor-gating node ND_{PG18}. Therefore, the pull-up transistors upPM[1]~upPM[4] have the same ON/OFF states. On the other hand, the source terminals of the pull-down transistors dnNM[1]-dnNM[K] are all electrically connected to the ground voltage node Gnd, and the gate terminals are all electrically connected to the pull-down transistor-gating node ND_{NG18}. Therefore, the pull-down transistors dnNM[1]-dnNM[4] have the same ON/OFF states.

The drain terminal of the pull-up transistor upPM[k] and the drain terminal of the pull-down transistor dnNM[k] are electrically connected to the transistor-path output node ND_{Rout_ts}[k]. Moreover, the transistor-path output impedance Rout_ts[k] is electrically connected between the transistor-path output node ND_{Rout_ts}[k] and the driver output node NDₒᵤₜ. The variables k and K are positive integers, and k≤K. For example, the drain terminal of the pull-up transistor upPM[1] and the drain terminal of the pull-down transistor dnNM[1] are electrically connected to the transistor-path output node ND_{Rout_ts}[1]. Moreover, the transistor-path output impedance Rout_ts[1] is electrically connected between the transistor-path output node ND_{Rout_ts}[1] and the driver output node NDₒᵤₜ.

Since the transistor-path output impedances Rout_ts[1]~Rout_ts[K] are connected in parallel, it can be derived from the descriptions with reference to FIGS. 18A and 18B that the equivalent output impedance Rout_eq is equivalent to the parallel connection of the transistor-path output impedances Rout_ts[1]~Rout_ts[K]. That is, the equivalent output impedance Rout_eq=(Rout_ts[1]//Rout_ts[2]// . . . //Rout_ts[K]).

In order to maintain the resistance value of the equivalent output impedance Rout_eq for larger variable K, it is necessary to use the transistor-path output impedances Rout_ts[1]~Rout_ts[K] with larger resistance values. In this way, the resistance value of the equivalent output impedance Rout_eq can be maintained even though the variable K is larger. However, using transistor-path output impedances Rout_ts[1]~Rout_ts[K] with larger resistance values also means that a larger circuit area is required.

Therefore, in actual applications, although the electrostatic protection function can be provided by increasing the number of the pull-up transistors upPM[1]~upPM[K] and the pull-down transistors dnNM[1]~dnNM[K], the value of the variable K should be determined according to the total area occupied by the pull-up transistors upPM[1]~upPM[K], the pull-down transistors dnNM[1]~dnNM[K], the capacitor-path output impedance Rout_cp and the transistor-path output impedances Rout_ts[1]~Rout_ts[K].

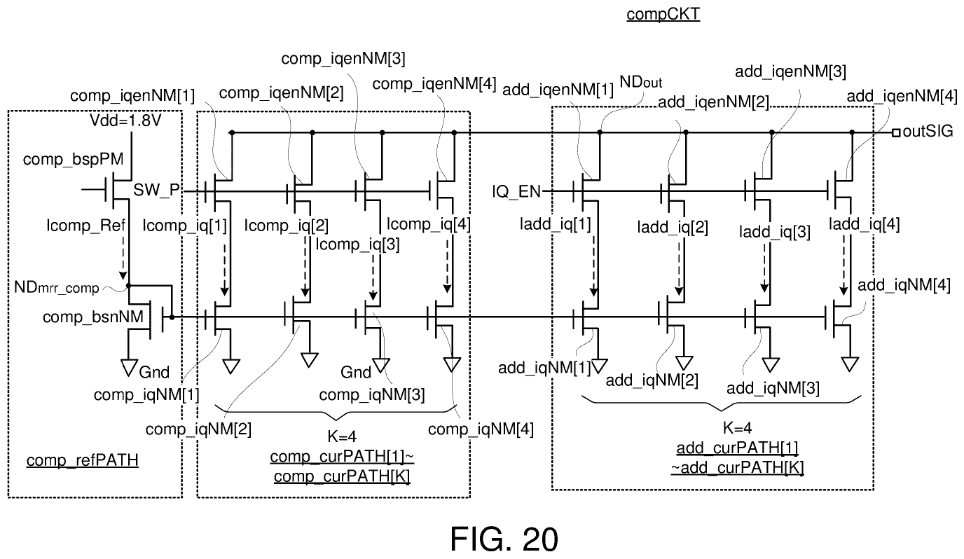

If the number of the pull-up transistors upPM[1]~upPM[K] and the pull-down transistors dnNM[1]~dnNM[K] in the driver portDRV is increased for electrostatic protection as described in FIG. 19, the number of the compensation current-paths comp_curPATH[1]~comp_curPATH[K] and the number of the additional current-paths add_curPATH[1]~add_curPATH[K] also need to be adjusted accordingly. In FIG. 20, it is assumed that K=4 compensation current-paths comp_curPATH[1]~comp_curPATH[4] and K=4 additional current-paths add_curPATH[1]~add_curPATH[4] are set in the compensation circuit compCKT.

Please refer to FIG. 20, which is a schematic diagram illustrating that compensation current-paths comp_curPATH[1]~comp_curPATH[4] and additional current-paths add_curPATH[1]~add_curPATH[4] are set in parallel in the driver portDRV of FIG. 19. In a concise manner, FIG. 20 only shows the compensation circuit compCKT.

In FIG. 20, the compensation circuit compCKT includes a compensation reference current-path comp_refPATH and compensation current-paths comp_curPATH[1]~comp_curPATH[4]. The compensation reference current-path comp_refPATH includes a compensation pull-up bias transistor comp_bspPM and a compensation pull-down bias transistor comp_bsnNM for the compensation reference current I_{comp_ref}. The compensation current-path comp_curPATH[k] (k=1-4) includes a compensation current-path enable transistor comp_iqenNM[k] and a compensation current-path transistor comp_iqNM[k]. When the compensation reference current I_{comp_ref} (10 μA, for example) is generated, a corresponding compensation current I_{comp_iq}[k](20 μA, for example) is also generated in the compensation current-path comp_curPATH[k].

The smaller capacitance value the pull-up capacitor Cup has, the poorer alternating current (hereinafter, AC) stability the driver portDRV has. At this time, the additional current-path add_curPATH can be selected to improve the AC stability of the driver portDRV.

FIG. 20 shows the structure in an example of variable K=4 and using the additional current-paths add_curPATH[1]~add_curPATH[K]. The additional current-path add_curPATH[k] (k=1~4) includes an additional current-path enable transistor add_iqenNM[k] and an additional current-path transistor add_iqNM[k]. Both the additional current-path enable transistor add_iqenNM[k] and the additional current-path transistor add_iqNM[k] are NMOS transistors.

Please refer to both FIGS. 16 and 20. The waveforms of FIG. 16 show that the additional current-path enable-signal IQ_EN is at a high logic-level H (IQ_EN=H=1.8V) when the driver portDRV is in the rising-transition phase PH1 and the high-level stable phase PH2. Therefore, the additional current-path add_curPATH[k] generates an additional current I_{add_iq}[k](20 μA, for example) during the rising-transition phase PH1 and the high-level stable phase PH2. The value of the variable K, the current value of the compensation reference current I_{comp_ref}, the current value of the compensation current I_{comp_iq}[k], and the current value of the additional current I_{add_iq}[k] in the example are not used to limit actual applications.

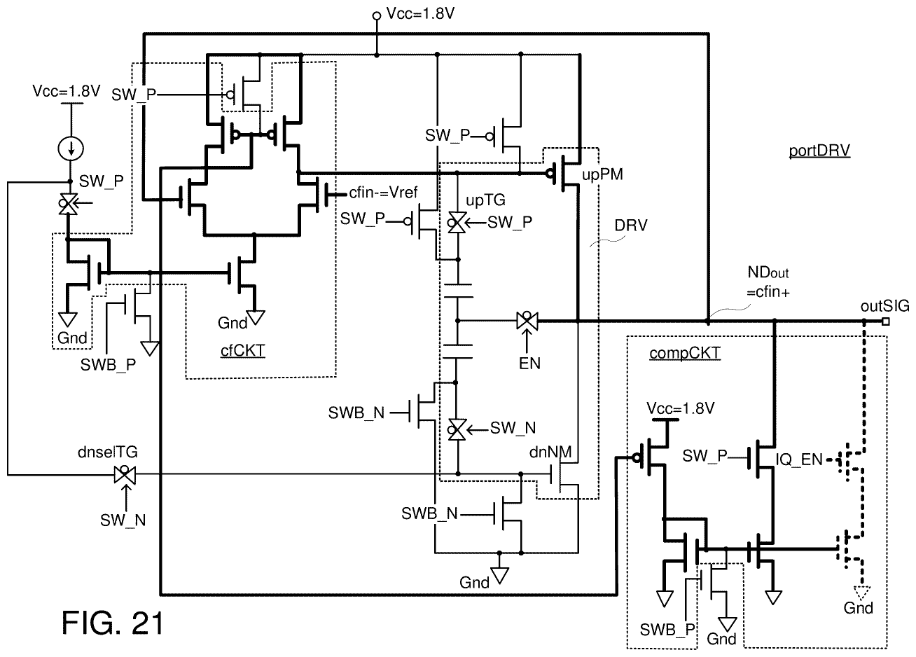

Please refer to FIG. 21, which is a schematic diagram illustrating that in the driver portDRV according to the present disclosure, the combination of the comparison circuit cfCKT, the pull-up transistor upPM, and the compensation circuit compCKT jointly function as a low-dropout regulator LDO. Please refer to both FIGS. 8 and 21. The circuit components and connections in FIG. 21 are the same as those shown in FIG. 8.

In FIG. 21, the circuit components and connections of the comparison circuit cfCKT, the pull-up transistor upPM, and the compensation circuit compCKT are marked with thick lines. In this diagram, the circuit components and connections of the comparison circuit cfCKT, the pull-up transistor upPM, and the compensation circuit compCKT constitute an architecture equivalent to a low-dropout regulator LDO. When the driver portDRV is in the high-level stable phase PH2, the low-dropout regulator LDO architecture can stably maintain the driver output signal outSIG to be equivalent to the reference voltage Vref. Therefore, the driver portDRV, according to the present disclosure, utilizes the existing circuit to perform the function of the low-dropout regulator LDO, so as to reduce the required circuit area.

Compared with the conventional technology, the driver portDRV, according to the present disclosure, has at least the following advantages. The driver portDRV does not need to set up a low-dropout regulator additionally. Instead, only one operational amplifier and a single-stage driving circuit are set up, and only one reference voltage Vref is required. Compared with the conventional technology, the driver portDRV, according to the present disclosure, can be implemented with simpler circuits to achieve power saving and area saving, and further reduce the production cost. In actual applications, the uses of the power-saving driver portDRV proposed in the present disclosure are not limited. For example, in addition to serving as a MIPI port physical layer driver, it can also be applied to a display driver circuit or other driver circuit. These application-related matters need not be discussed here.

While the disclosure has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A driver comprising:
a switching-signal generation circuit, configured for generating a positive pull-up switching-signal, a negative pull-up switching-signal, a positive pull-down switching-signal, and a negative pull-down switching-signal according to a driving enable-signal and a driver input signal;
a comparison circuit, electrically connected to a first constant voltage node having a first constant voltage and a second constant voltage node having a second constant voltage, comprising:
a non-inverting input-terminal electrically connected to a driver output node of the driver;
an inverting input-terminal, configured for receiving a reference voltage, wherein the reference voltage is higher than the second constant voltage, and the reference voltage is lower than the first constant voltage;
a non-inverting output-terminal; and
an inverting output-terminal electrically connected to a pull-up transistor-gating node;
a driving circuit, comprising:
a pull-up circuit, electrically connected to the switching-signal generation circuit and the comparison circuit, configured for selectively adjusting a voltage of the driver output node according to the positive pull-up switching-signal and a voltage of the pull-up transistor-gating node; and
a pull-down circuit, electrically connected to the switching-signal generation circuit, configured for selectively adjusting the voltage of the driver output node according to the positive pull-down switching-signal and a voltage of a pull-down transistor-gating node; and
a port control module, electrically connected to the switching-signal generation circuit, the comparison circuit and the driving circuit, configured for setting the voltage of the pull-up transistor-gating node and the voltage of the pull-down transistor-gating node according to the positive pull-up switching-signal, the negative pull-up switching-signal, the positive pull-down switching-signal, and the negative pull-down switching-signal.

2. The driver according to claim 1, wherein
the pull-up circuit comprises:
K pull-up transistors, electrically connected to the pull-up transistor-gating node and the first constant voltage node, configured for selectively setting the driver output node to have the first constant voltage according to the voltage of the pull-up transistor-gating node;
a pull-up transmission-gate, electrically connected to the switching-signal generation circuit and the pull-up transistor-gating node, configured for being selectively turned on according to the positive pull-up switching-signal; and
a pull-up capacitor electrically connected to the pull-up transmission-gate, and
the pull-down circuit comprises:
K pull-down transistors, electrically connected to the pull-down transistor-gating node and the second constant voltage node,
configured for selectively setting the driver output node to have the second constant voltage according to the voltage of the pull-down transistor-gating node;
a pull-down transmission-gate, electrically connected to the switching-signal generation circuit and the pull-down transistor-gating node, configured for being selectively turned on according to the positive pull-down switching-signal; and
a pull-down capacitor electrically connected to the pull-up capacitor and the pull-down transmission-gate,
wherein a k-th pull-up transistor among the K pull-up transistors is electrically connected to a k-th pull-down transistor among the K pull-down transistors, wherein k and K are positive integers, and k is smaller than or equal to K.

3. The driver according to claim 2, wherein
when the pull-up transmission-gate is turned on according to the positive pull-up switching-signal, the pull-down transmission-gate is turned off according to the positive pull-down switching-signal; and
when the pull-up transmission-gate is turned off according to the positive pull-up switching-signal, the pull-down transmission-gate is turned on according to the positive pull-down switching-signal.

4. The driver according to claim 2, wherein the port control module further comprises:
a reference current source, electrically connected to the first constant voltage node, configured for providing a reference current; and
a path-selection circuit, comprising:
a pull-up path-selection transmission-gate, electrically connected to the reference current source and the comparison circuit, configured for being selectively turned on according to the positive pull-up switching-signal, thereby allowing the reference current to flow to the comparison circuit; and
a pull-down path-selection transmission-gate, electrically connected to the reference current source and the pull-down circuit, configured for being selectively turned on according to the positive pull-down switching-signal, thereby allowing the reference current to flow to the pull-down circuit.

5. The driver according to claim 4, wherein
when the driving enable-signal is at a first logic-level, the pull-up path-selection transmission-gate and the pull-down path-selection transmission-gate are synchronously turned off; and
when the driving enable-signal is at a second logic-level, the pull-up path-selection transmission-gate and the pull-down path-selection transmission-gate are alternately turned on.

6. The driver according to claim 4, where in the port control module further comprises:
a pull-up disable transistor, electrically connected to the first constant voltage node and the pull-up transistor-gating node, configured for being selectively turned on according to the positive pull-up switching-signal, wherein when the pull-up disable transistor is turned on, the pull-up disable transistor sets the pull-up transistor-gating node to the first constant voltage, thereby turning off the K pull-up transistors; and
a pull-up bypass transistor, electrically connected to the first constant voltage node, the pull-up transmission-gate, and the pull-up capacitor, configured for being selectively turned on according to the positive pull-up switching-signal.

7. The driver according to claim 6, wherein
when the driving enable-signal is at a first logic-level, the pull-up disable transistor and the pull-up bypass transistor are turned on, and the K pull-up transistors and the pull-up transmission-gate are turned off; and
when the driving enable-signal is at a second logic-level, the pull-up disable transistor and the pull-up bypass transistor are selectively turned on, wherein when the driving enable-signal is at the second logic-level, and the pull-up disable transistor and the pull-up bypass transistor are turned on, the K pull-up transistors and the pull-up transmission-gate are turned off, and
when the driving enable-signal is at the second logic-level, and the pull-up disable transistor and the pull-up bypass transistor are turned off, the K pull-up transistors and the pull-up transmission-gate are turned on.

8. The driver according to claim 4, wherein the port control module further comprises:
a pull-down disable transistor, electrically connected to the second constant voltage node and the pull-down transistor-gating node, configured for being selectively turned on according to the negative pull-down switching-signal, wherein when the pull-down disable transistor is turned on, the pull-down disable transistor sets the pull-down transistor-gating node to the second constant voltage, thereby turning off the K pull-down transistors; and
a pull-down bypass transistor, electrically connected to the second constant voltage node, the pull-down transmission-gate, and the pull-down capacitor, configured for being selectively turned on according to the negative pull-down switching-signal.

9. The driver according to claim 8, wherein
when the driving enable-signal is at a first logic-level, the pull-down disable transistor and the pull-down bypass transistor are turned on, and the K pull-down transistors and the pull-down transmission-gate are turned off; and
when the driving enable-signal is at a second logic-level, the pull-down disable transistor and the pull-down bypass transistor are selectively turned on, wherein
when the driving enable-signal is at the second logic-level, and the pull-down disable transistor and the pull-down bypass transistor are turned on, the K pull-down transistors and the pull-down transmission-gate are turned off, and when the driving enable-signal is at the second logic-level, and the pull-down disable transistor and the pull-down bypass transistor are turned off, the K pull-down transistors and the pull-down transmission-gate are turned on.

10. The driver according to claim 2, wherein the driving circuit further comprises:
a driving enable transmission-gate, electrically connected to the pull-up capacitor and the pull-down capacitor, configured for being selectively turned on according to the driving enable-signal;
a capacitor-path output impedance, electrically connected to the driving enable transmission-gate and the driver output node; and
K transistor-path output impedances, wherein a k-th transistor-path output impedance among the K transistor-path output impedances is electrically connected to the k-th pull-up transistor and the k-th pull-down transistor.

11. The driver according to claim 10, wherein
when the driving enable transmission-gate is turned off, the pull-up circuit and the pull-down circuit stop setting the voltage of the driver output node, and the driver output node is floating.

12. The driver according to claim 10, wherein
when the driving enable transmission-gate is turned on, the voltage of the driver output node changes with the driver input signal, wherein when the driver input signal changes from a first logic-level to a second logic-level, the voltage of the driver output node rises from the second constant voltage to the reference voltage;
when the driver input signal remains at the second logic-level, the voltage of the driver output node remains at the reference voltage;
when the driver input signal changes from the second logic-level to the first logic-level, the voltage of the driver output node falls from the reference voltage to the second constant voltage; and
when the driver input signal remains at the first logic-level, the voltage of the driver output node remains at the second constant voltage.

13. The driver according to claim 2, further comprising a compensation circuit, comprising:
a compensation reference current-path, electrically connected to the port control module, the non-inverting output-terminal of the comparison circuit, the first constant voltage node, and the second constant voltage node, configured for selectively generating a compensation reference current between the first constant voltage node and the second constant voltage node according to the voltage of the non-inverting output-terminal of the comparison circuit and the negative pull-up switching-signal; and
K compensation current-paths, electrically connected to the switching-signal generation circuit, the port control module, the driver output node, and the second constant voltage node, configured for selectively and synchronously generating K compensation currents between the driver output node and the second constant voltage node according to the positive pull-up switching-signal and the negative pull-up switching-signal.

14. The driver according to claim 13, wherein the port control module further comprises:
a compensation disable transistor, electrically connected to the switching-signal generation circuit, the compensation reference current-path, and the K compensation current-paths, configured for being selectively turned off according to the negative pull-up switching-signal to interrupt the compensation reference current-path and the K compensation current-paths.

15. The driver according to claim 14, wherein the compensation circuit further comprises:
K additional current-paths, electrically connected to the compensation reference current-path, the K compensation current-paths, and the compensation disable transistor, configured for selectively and synchronously generating K additional currents according to an additional current-path enable-signal,
wherein the compensation disable transistor is selectively turned off to interrupt the K additional current-paths according to the negative pull-up switching-signal.

16. The driver according to claim 15, further comprising:
an additional current-path enable circuit, electrically connected to the switching-signal generation circuit and the K additional current-paths, configured for receiving the positive pull-up switching-signal from the switching-signal generation circuit and receiving an external enable-signal for the K additional current-paths from an external controller,
wherein the additional current-path enable circuit determines a logic-level of the additional current-path enable-signal according to the positive pull-up switching-signal and the external enable-signal for the K additional current-paths.

17. The driver according to claim 13, wherein the comparison circuit, the K pull-up transistors, and the compensation circuit collectively form a low-dropout regulator.

18. The driver according to claim 1, wherein the comparison circuit further comprises:
a first current-mirror, comprising:
a first positive transistor, electrically connected to the non-inverting output-terminal of the comparison circuit, the port control module, and the first constant voltage node; and
a first negative transistor, electrically connected to the inverting output-terminal of the comparison circuit, the port control module, and the first constant voltage node;
a differential input circuit, comprising:
a positive differential-input transistor electrically connected to the non-inverting output-terminal and the non-inverting input-terminal of the comparison circuit; and
a negative differential-input transistor electrically connected to the inverting output-terminal and the inverting input-terminal of the comparison circuit; and
a second current-mirror, comprising:
a second positive transistor electrically connected to the port control module and the second constant voltage node; and
a second negative transistor electrically connected to the port control module, the positive differential-input transistor, the negative differential-input transistor, and the second constant voltage node.

19. The driver according to claim 18, wherein the port control module further comprises:
a first current-mirror disable transistor, electrically connected to the first constant voltage node, the switching-signal generation circuit, the first positive transistor of the first current-mirror, and the first negative transistor of the first current-mirror, configured for selectively conducting the first constant voltage to the non-inverting output-terminal of the comparison circuit according to the positive pull-up switching-signal, thereby turning off the first positive transistor of the first current-mirror and the first negative transistor of the first current-mirror; and
a second current-mirror disable transistor, electrically connected to the second constant voltage node, the switching-signal generation circuit, the second positive transistor of the second current-mirror, and the second negative transistor of the second current-mirror, selectively conducting the second constant voltage to the second positive transistor of the second current-mirror and the second negative transistor of the second current-mirror according to the negative pull-up switching-signal, thereby turning off the second positive transistor of the second current-mirror and the second negative transistor of the second current-mirror,
wherein the first current-mirror disable transistor and the second current-mirror disable transistor are synchronously turned on or off.

20. The driver according to claim 1, wherein
when the driving enable-signal is at a first logic-level, the switching-signal generation circuit sets the positive pull-up switching-signal and the positive pull-down switching-signal to the first logic-level, and the switching-signal generation circuit sets the negative pull-up switching-signal and the negative pull-down switching-signal to a second logic-level; and
when the driving enable-signal is at the second logic-level, the switching-signal generation circuit sets the positive pull-up switching-signal and the negative pull-down switching-signal according to a logic-level of the driver input signal, and the switching-signal generation circuit sets the negative pull-up switching-signal and the positive pull-down switching-signal according to an opposite logic-level of the driver input signal.
